(19) United States
(12) Patent Application Publication
(10) Pub. No.: US 2015/0264810 A1
(43) Pub. Date: Sep. 17, 2015

(54) CIRCUIT BOARD AND MANUFACTURING METHOD OF CIRCUIT BOARD

(71) Applicant: FUJITSU LIMITED, Kawasaki-shi (JP)

(72) Inventors: Shunji BABA, Yokohama (JP); Manabu WATANABE, Yokohama (JP); Kenji FUKUZONO, Kawasaki (JP); Satoshi OHSAWA, Kawasaki (JP); Tetsuro YAMADA, Kawasaki (JP); Akihiro WAKABAYASHI, Kawasaki (JP); Yasushi MASUDA, Kawasaki (JP); Yohei MIURA, Kawasaki (JP)

(21) Appl. No.: 14/636,356

(22) Filed: Mar. 3, 2015

(30) Foreign Application Priority Data
Mar. 11, 2014 (JP) 2014-047605

(51) Int. Cl. H05K 1/11; H05K 3/30; H05K 3/10; H05K 1/18

(52) U.S. Cl. CPC H05K 1/115; H05K 1/18; H05K 3/301; H05K 3/103; H05K 2201/095

(57) ABSTRACT

A circuit board includes: a substrate; a through hole formed in the substrate; and a connection terminal provided in the through hole; wherein the connection terminal includes a pedestal portion provided within the through hole and a pin which is provided at a center of the pedestal portion and extends from the pedestal portion toward a first surface of the substrate, so that a first end portion protrudes from the first surface.

### CROSS-REFERENCE TO RELATED APPLICATION

This application is based upon and claims the benefit of priority from the prior Japanese Patent Application No. 2014-047605 filed on Mar. 11, 2014, the entire contents of which are incorporated herein by reference.

### FIELD

The embodiments discussed herein are related to a circuit board and a manufacturing method of a circuit board.

### BACKGROUND

A technique which electrically connects circuit boards, such as printed boards, to each other using a connector provided in one of the circuit boards and a connector provided in the other circuit board is known. For example, a technique which electrically connects circuit boards to each other using a plug (male) as one connector and a socket (female) as the other connector is known.

A related technique is disclosed in, for example, Japanese Laid-Open Patent Publication No. 2006-178967.

When the circuit boards are connected to each other by two connectors, a gap between the circuit boards is increased due to thicknesses of the connectors, so that a wiring distance may be increased and a size of the device may be increased.

When a technique which replaces one of the connectors with a pin provided in one circuit board and inserts the pin into the connector of the other circuit board to connect the pin with the connector is used, the above-mentioned problems may be suppressed. However, in the connection between the pin and the connector, when the pin and an insertion port of the connector, which are connected to each other, are misaligned, stress occurs at the pin inserted into and connected to the connector, so that a connection portion thereof may be broken or connection reliability may be lowered.

Further, such a problem may occur not only when circuit boards are connected to each other using connectors but also when a circuit board and various electronic components are connected to each other using connectors.

### SUMMARY

According to an aspect of the present invention, there is provided a circuit board, including: a substrate; a through hole formed in the substrate; and a connection terminal provided in the through hole, in which the connection terminal includes a pedestal portion provided within the through hole and a pin which is provided at a center of the pedestal portion and extends from the pedestal portion toward a first surface of the substrate, so that a first end portion protrudes from the first surface.

Further, according to another aspect of the present invention, there is provided a method of manufacturing a circuit board.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a view illustrating an example of a circuit board according to a first embodiment;

FIGS. 2A and 2B are views illustrating an example of a component-mounted circuit board according to the first embodiment;

FIGS. 3A and 3B are views illustrating an example of a connecting process of a connection terminal and a connector according to the first embodiment;

FIGS. 4A and 4B are views illustrating an example of a connecting process of a connection terminal and a connector according to another embodiment;

FIGS. 5A and 5B are views illustrating an example of a through hole portion according to another embodiment;

FIG. 6 is a (first) view illustrating an example of a component-mounted circuit board according to a second embodiment;

FIG. 7 is a (second) view illustrating an example of a component-mounted circuit board according to the second embodiment;

FIG. 8 is a (third) view illustrating an example of a component-mounted circuit board according to the second embodiment;

FIGS. 9A and 9B views illustrating an example of a power supply board according to the second embodiment;

FIGS. 10A and 10B views illustrating an example of a connecting process of a connection terminal and a connector according to the second embodiment;

FIG. 11 is a (first) view illustrating an example of a component-mounted circuit board according to another embodiment;

FIG. 12 is a (second) view illustrating an example of a component-mounted circuit board according to another embodiment;

FIG. 13 is a (third) view illustrating an example of a component-mounted circuit board according to another embodiment;

FIGS. 14A to 14F are views illustrating an example of a forming method of a connection terminal according to the second embodiment;

FIGS. 15A and 15B are (first) views illustrating an example of a manufacturing method of a component-mounted circuit board according to the second embodiment;

FIGS. 16A and 16B are (second) views illustrating an example of a manufacturing method of a component-mounted circuit board according to the second embodiment;

FIG. 17 is an explanatory view of a first modified embodiment;

FIG. 18 is an explanatory view of a second modified embodiment;

FIGS. 19A and 19B are explanatory views of a third modified embodiment;

FIGS. 20A and 20B are explanatory views of a fourth modified embodiment;

FIGS. 21A and 21B are explanatory views of a fifth modified embodiment;

FIG. 22 is an explanatory view of a sixth modified embodiment;

FIG. 23 is an explanatory view of a seventh modified embodiment;

FIGS. 24A and 24B explanatory views of an eighth modified embodiment; and

FIGS. 25A and 25B are views illustrating an example of a component-mounted circuit board according to a third embodiment.

### DESCRIPTION OF EMBODIMENTS

A first embodiment will be described first.

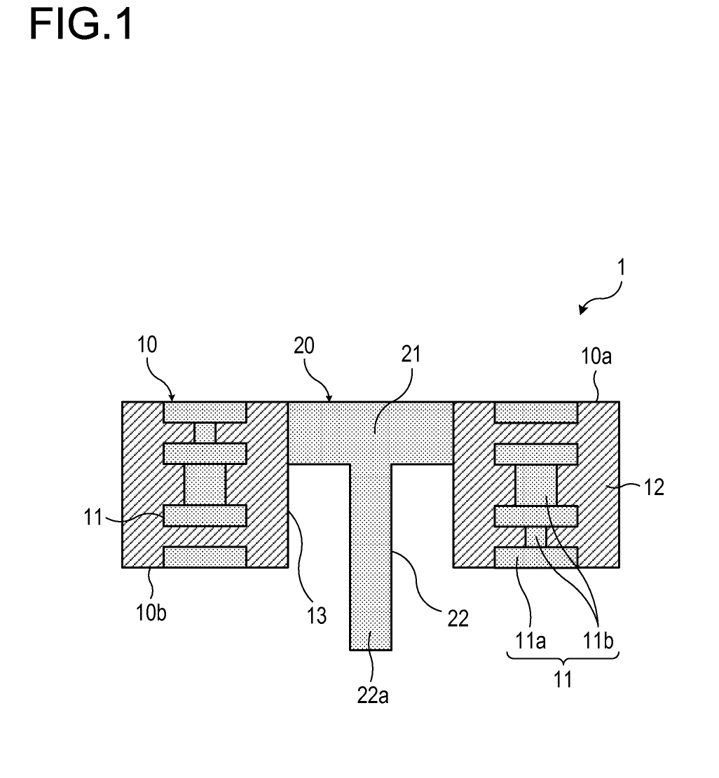

FIG. 1 is a view illustrating an example of a circuit board according to a first embodiment. In FIG. 1, a cross-section of a main part of a circuit board according to the first embodiment is schematically illustrated.

A circuit board 1 illustrated in FIG. 1 includes a substrate 10 and a connection terminal 20.

The circuit board 1 is, for example, a printed board. Examples of the printed board may include a system board including a package substrate (circuit board) on which various electronic components, such as a semiconductor package (a semiconductor device) mounted with a semiconductor chip (a semiconductor element) is mounted.

As illustrated in FIG. 1, the substrate 10 of the circuit board 1 includes a conductor portion 11 (a wiring 11a and a via 11b) which is provided in a front surface 10a, a rear surface 10b and the inside thereof, and an insulating portion 12 which covers the conductor portion 11. Here, as the circuit board 1, a multilayered printed board including two layers of the wiring 11a in the insulating portion 12 is exemplified, but the number of layers of the wiring therein is not limited thereto. For example, the circuit board 1 may be a double sided printed board in which the wiring 11a provided on the front surface 10a and the wiring 11a provided on the rear surface 10b are connected by the via 11b which passes through the insulating portion 12.

The substrate 10 has a through hole 13 which penetrates between the front surface 10a and the rear surface 10b. A conductor layer may be formed on a side wall of the through hole 13 to form a conductive portion (a through hole portion) which provides conduction between the front surface 10a and the rear surface 10b.

The connection terminal 20 is provided in the through hole 13 of the substrate 10. The connection terminal 20 includes a plate-like pedestal portion 21 having a predetermined thickness and a pin 22 which is provided at a location further inside than a periphery side of the pedestal portion 21, for example, at a center of the pedestal portion 21.

Various conductive materials may be used for the pedestal portion 21 and the pin 22. As the conductive materials used for the pedestal portion 21 and the pin 22, a metal material such as copper (Cu), aluminum (Al), gold (Au), silver (Ag), or nickel (Ni) may be used. The pedestal portion 21 and the pin 22 include one or more kinds of the metal materials. For example, the pedestal portion 21 and the pin 22 may be formed of Cu, and a separate metal film such as Au or solder may be formed on surfaces of the pedestal portion 21 and the pin 22 formed of Cu. Further, the pedestal portion 21 and the pin 22 may be formed of an alloy containing several kinds of metals.

A thickness of the pedestal portion 21 is set to be smaller than a thickness (a length in an axial direction of the through hole 13) of the substrate 10. The pedestal portion 21 having the thickness as described above is provided to be located inside the through hole 13.

The pin 22 is provided, for example, at the center of the pedestal portion 21 and a planar size thereof is smaller than a planar size of the pedestal portion 21. The pin 22 is provided so as to extend from the pedestal portion 21 located inside the through hole 13 toward the rear surface 10b of the substrate 10. A length of the pin 22 is set such that an end portion (a distal portion) 22a in a direction extending from the pedestal portion 21 protrudes from the rear surface 10b of the substrate 10. The length of the distal portion 22a protruding from the rear surface 10b of the substrate 10 is set based on, for example, a dimension (depth) of an insertion port (terminal) of a connection counterpart side into which the pin 22 is inserted and a distance (gap) between the circuit board 1 and the connection counterpart after the circuit board 1 and the connection counterpart are connected to each other, which will be described below.

As described above, the pin 22 is connected to the pedestal portion 21 which is located inside the through hole 13 of the substrate 10 at a base portion side opposite to the distal portion 22a and extends to the rear surface 10b of the substrate 10 in the through hole 13, so that the distal portion 22a protrudes from the rear surface 10b. A length and a diameter of the pin 22 are set to have flexibility such that the distal portion 22a is bent with a connection portion (base portion) between the pin 22 and the pedestal portion 21 as a fulcrum point. The pin 22 has a structure in which the pin 22 extends in the through hole 13 (from the pedestal portion 21 located inside the through hole 13) so as to secure a length which allows the flexibility. A thickness of the pedestal portion 21 provided inside the through hole 13 is set based on the thickness of the substrate 10 and the length and the diameter of the pin 22.

Various electronic components such as a semiconductor package or other circuit substrates are mounted on the circuit board 1 having the above-described configuration. Here, a device (an electronic device) in which an electronic component is mounted on the circuit board 1 is referred to as a component-mounted circuit board.

Next, the connection between the circuit board 1 and the electronic component will be described.

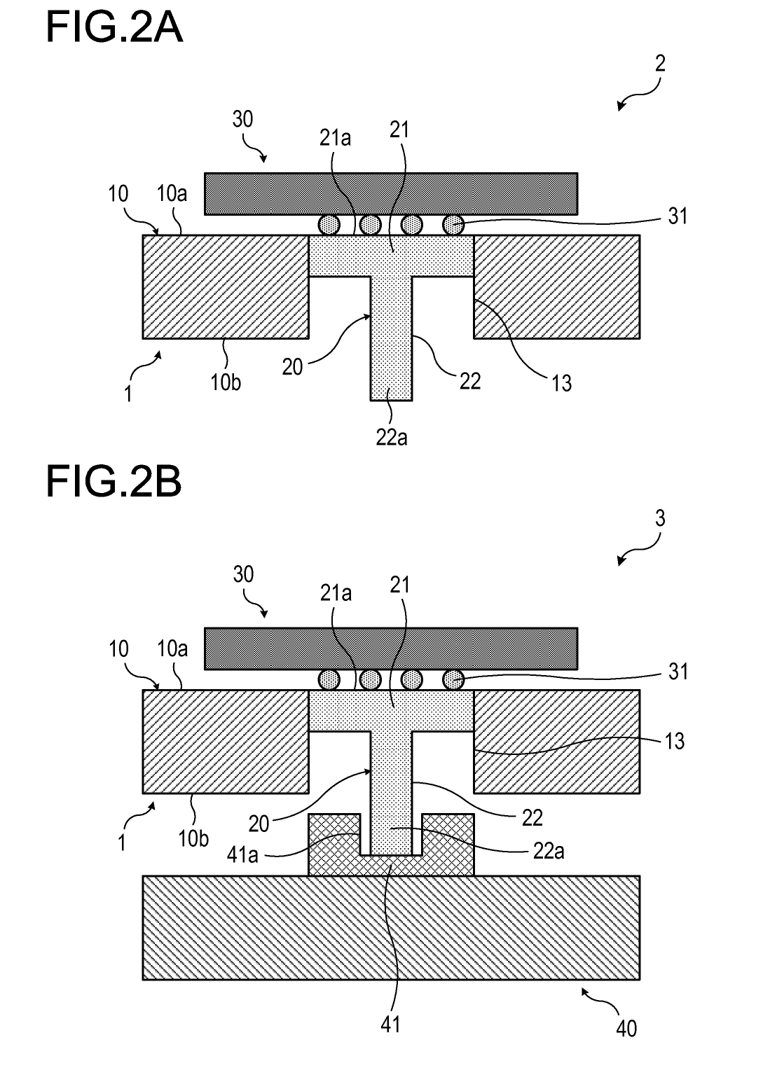

FIGS. 2A and 2B are views illustrating an example of a component-mounted circuit board according to the first embodiment. FIG. 2A schematically illustrates a cross-section of a main part of a first example of the component-mounted circuit board according to the first embodiment and FIG. 2B schematically illustrates a cross-section of a main part of a second example of the component-mounted circuit board according to the first embodiment. In the meantime, the conductor portion 11 illustrated in FIG. 1 will be omitted.

For example, as in a component-mounted circuit board 2 illustrated in FIG. 2A, an electronic component 30 having a plurality of terminals (bumps) 31 such as a semiconductor package including a semiconductor chip or, a semiconductor chip, is mounted on the circuit board 1.

The bumps 31 of the electronic component 30 are, for example, solder bumps such as solder balls. The electronic component 30 is disposed such that an arrangement surface side of the bumps 31 faces the front surface 10a of the circuit board 1. Then, the electronic component 30 is electrically connected to the circuit board 1 through the bumps 31. Here, in the exemplified structure, the bumps 31 provided at a center of the electronic component 30 are bonded onto a surface 21a of the pedestal portion 21 of the connection terminal 20 of the circuit board 1. When the bumps 31 are directly bonded to the pedestal portion 21, the connection terminal 20 and the bumps 31 may be electrically connected to each other with a low resistance.

Further, the bumps 31 of the electronic component 30 may be provided in other regions, for example, at an outer periphery of the electronic component 30 in addition to the region illustrated in FIGS. 2A and 2B. The bumps 31 in the regions are bonded to a wiring (for example, the wiring 11a of FIG. 1) which is provided on the front surface 10a of the circuit board 1.

Further, a component-mounted circuit board 3 illustrated in FIG. 2B has a structure in which the connection terminal 20 of the circuit board 1 of the component-mounted circuit board 2 as illustrated in FIG. 2A is connected to an electronic component 40 such as a circuit board which is disposed to face the rear surface 10b of the circuit board 1. For example, when the electronic component 40 is a circuit board, the circuit board may serve as a power supply board which supplies power to the circuit board 1 which is a system board.

The electronic component 40 illustrated in FIG. 2B has a connector 41. The connector 41 includes an insertion port 41a which is provided at a position corresponding to the connection terminal 20 of the circuit board 1, and into which the pin 22 of the connection terminal 20 is inserted. The insertion port 41a of the connector 41 has a concave terminal structure which is electrically connected to an internal structure (a conductor portion such as a wiring or a via) of the electronic component 40. When the pin 22 of the connection terminal 20 is inserted into the insertion port 41a of the connector 41, the circuit board 1 and the electronic component 40 are electrically connected to each other through the connection terminal 20. The pin 22 of the connection terminal 20 may be inserted into or removed from the insertion port 41a of the connector 41.

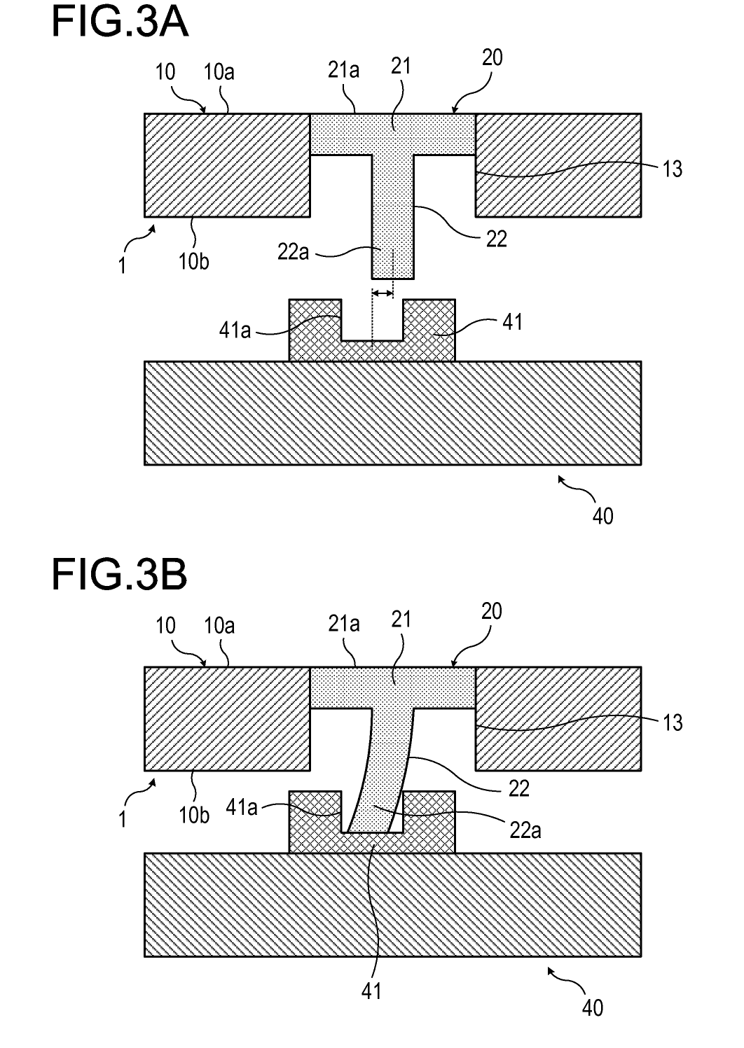

Here, connection using the connection terminal 20 and the connector 41 will be described again with reference to FIGS. 3A to 5B.

FIGS. 3A and 3B are views illustrating an example of a connecting process of a connection terminal and a connector according to the first embodiment. FIG. 3A schematically illustrates a cross-section of a main part of an example of the connection terminal and the connector according to the first embodiment before they are connected to each other and FIG. 3B schematically illustrates a cross-section of a main part of an example of the connection terminal and the connector according to the first embodiment after they are connected to each other.

When the circuit board 1 including the connection terminal 20 provided in the through hole 13 of the substrate 10 is connected to the electronic component 40 provided with the connector 41, first, as illustrated in FIG. 3A, the circuit board 1 and the electronic component 40 are disposed such that the pin 22 of the connection terminal 20 faces the connector 41. Then, the circuit board 1 and the electronic component 40 becomes close to each other to insert the pin 22 into the insertion port 41a of the connector 41.

When the pin 22 is inserted, a position of the pin 22 and a position of the insertion port 41a of the connector 41 may be misaligned. For example, when an arrangement position of the connection terminal 20 in the circuit board 1 is shifted from a design value or an arrangement position of the connector 41 in the electronic component 40 is shifted from the design value, the pin 22 and the insertion port 41a may be misaligned. Further, due to an alignment error when the circuit board 1 and the electronic component 40 are disposed to face each other, the pin 22 and the insertion port 41a may be misaligned. FIG. 3A illustrates that the circuit board 1 and the electronic component 40 are disposed to face each other in a state where the pin 22 and the insertion port 41a are misaligned (axial positions of the pin 22 and the insertion port 41a are indicated by dotted lines).

The connection terminal 20 of the circuit board 1 includes the pedestal portion 21 located inside the through hole 13 of the substrate 10 and the pin 22 which extends from the pedestal portion 21 within the through hole 13 so that the distal portion 22a protrudes from the rear surface 10b of the substrate 10. In the connection terminal 20, the pin 22 is configured to extend in the through hole 13 so as to have a length and a diameter which exhibits flexibility with respect to a predetermined load.

Due to the connection terminal 20 described above, even though the pin 22 and the insertion port 41a of the connector 41 are misaligned as described above (see FIG. 3A), when the distal end of the pin 22 enters the insertion port 41a, the pin 22 is bent to be inserted into the insertion port 41a as illustrated in FIG. 3B. As described above, the pin 22 is bent to be inserted into the insertion port 41a of the connector 41, so that the circuit board 1 and the electronic component 40 are electrically connected to each other. Connection reliability of the circuit board 1 and the electronic component 40 may be improved by bending the pin 22 having a predetermined length and a predetermined diameter.

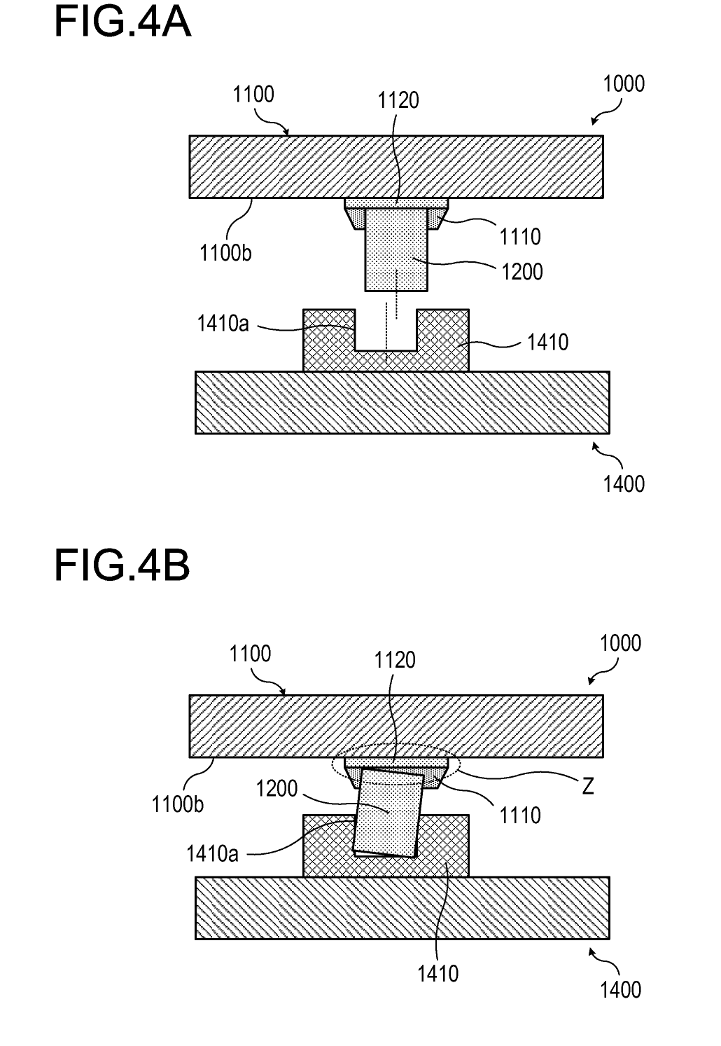

For comparison, an example of a connecting process of a connection terminal and a connector according to another embodiment will be illustrated in FIGS. 4A and 4B. FIG. 4A schematically illustrates a cross-section of a main part of an example of the connection terminal and the connector according to another embodiment before they are connected to each other and FIG. 4B schematically illustrates a cross-section of a main part of an example of the connection terminal and the connector according to another embodiment after they are connected to each other.

FIGS. 4A and 4B illustrate an exemplary connection between a circuit board 1000 and an electronic component 1400. In the circuit board 1000, a pin 1200 is connected to a conductor portion 1120 provided on a rear surface 1100b of the substrate 1100 using a bonding layer 1110. The electronic component 1400 is provided with a connector 1410 having an insertion port 1410a into which the pin 1200 is inserted.

As illustrated in FIG. 4A, in a state when the pin 1200 and the insertion port 1410a of the connector 1410 are misaligned (individual axial positions are indicated by dotted lines), when the pin 1200 is inserted into the insertion port 1410a as illustrated in FIG. 4B, stress occurs in the pin 1200. Due to the stress, a connection portion between the pin 1200 and the conductor portion 1120 may be broken as illustrated in a Z part in FIG. 4B or reliability of the connection portion may be lowered.

In contrast, the connection terminal 20 of the circuit board 1 is configured such that the pin 22 extends in the through hole 13, and has a length and a diameter to allow flexibility. Therefore, even though the pin 22 and the insertion port 41a of the connector 41 are misaligned, the pin 22 is bent to be inserted into the insertion port 41a. As described above, the pin 22 is configured to be bendable, so that the distortion caused by the misalignment is absorbed, thereby suppressing the stress which is shown in the pin 1200 described above from occurring. Therefore, the connection terminal 20 and the connector 41 may be connected to each other with high reliability.

Further, the pin 22 is connected to and supported by the pedestal portion 21 having a predetermined thickness. Therefore, even when the bumps 31 of the electronic component 30 are bonded onto the surface 21a of the pedestal portion 21 as illustrated in FIG. 2A and the pin 22 which is continued to the pedestal portion 21 at an opposite side to the bonding portion is bent, the distortion may be suppressed from occurring in the bonding portion between the pedestal portion 21 and the electronic component 30. From this point of view, a thickness of the pedestal portion 21 may be set to suppress the distortion from occurring in the bonding portion of the electronic component 30 bonded to the surface 21a when the pin 22 having a predetermined length and a predetermined diameter is inserted into the connector 41 and bent.

According to the connection terminal 20, it is possible not only to connect the pin 22 to the insertion port 41a of the connector 41 with high reliability as described above, but also to connect the bumps 31 of the electronic component 30 to the pedestal portion 21 with high reliability.

Further, since the pedestal portion 21 and the pin 22 become a conducting path between the front surface and the rear surface in the connection terminal 20 of the circuit board 1, an area (a cross-sectional area) of the conducting path may be increased as compared with a case where a through hole portion having a conductor layer provided on an inner wall of a through hole singly becomes a conducting path between the front surface and the rear surface.

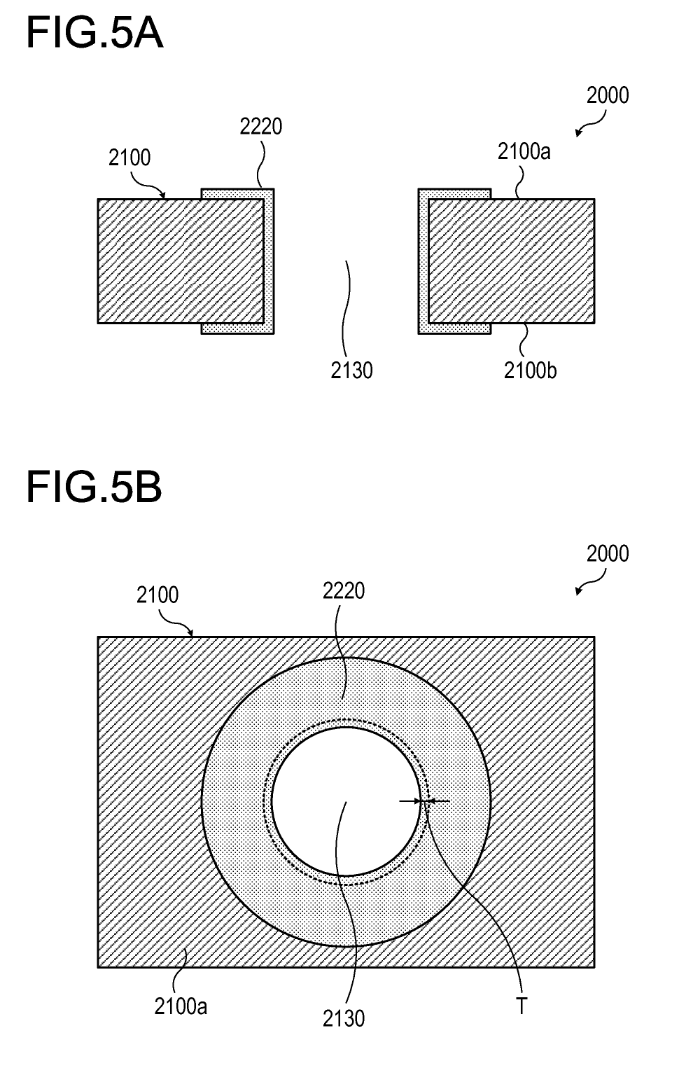

For comparison, here, an example of a through hole portion according to another embodiment will be illustrated in FIGS. 5A and 5B. FIG. 5A schematically illustrates a plan view of a main part of a through hole portion of a circuit board according to another embodiment and FIG. 5B schematically illustrates a cross-section of a main part of a through hole portion of a circuit board according to another embodiment.

A circuit board 2000 illustrated in FIGS. 5A and 5B includes a substrate 2100 in which a through hole 2130 is formed and a through hole portion having a conductor layer 2220 formed on an inner wall of the through hole 2130. The conductor layer 2220 extends to outer peripheries of the through hole 2130 at a front surface 2100a and a rear surface 2100b of the substrate 2100. In the circuit board 2000, for example, an inner portion (a hollow portion) of the through hole 2130 formed with the conductor layer 2220 is filled with resin, so that a top and a bottom of the through hole 2130 are further covered with a conductor layer (a land portion which is formed by so-called cover plating). For example, the pin 1200 (see FIG. 4) as described above is bonded to a location (the land portion) immediately below the through hole portion as illustrated in FIGS. 5A and 5B or to a location below a leading wiring which is provided on the substrate 2100 to extend from the through hole portion.

In the through hole portion of the circuit board 2000, an area (a cross-sectional area) of the conducting path between the front surface 2100a and the rear surface 2100b corresponds to the thickness of the conductor layer 2220 provided on the inner wall of the through hole 2130. In order to increase the area of the conducting path, a thickness T of the conductor layer 2220 within the through hole 2130 may be increased. However, it is not necessarily easy to form a thick conductor layer 2220 having a good film quality within the through hole 2130 in view of a plating technique, a manufacturing cost, and a manufacturing efficiency.

In contrast, the connection terminal 20 including the pedestal portion 21 within the through hole 13 and the pin 22 extending from the pedestal portion 21 is provided in the circuit board 1. The pin 22 connected to the pedestal portion 21 within the through hole 13 has a diameter which allows flexibility and may be a solid pin (which intentionally does not have a hollow portion). Therefore, it is possible to relatively easily obtain a structure in which the area (the cross-sectional area) of the conducting path is increased, so that the conducting is stably performed and high current used for a power supply may be stably conducted.

The circuit board 1 in a state where the pin 22 of the connection terminal 20 is inserted into the insertion port 41a of the connector 41 of the electronic component 40 as illustrated in FIG. 2B may be removed from the electronic component 40 by pulling the pin 22 of the connection terminal 20 out of the insertion port 41a of the connector 41.

For example, after the circuit board 1 and the electronic component 40 are connected to each other as illustrated in FIG. 2B, when a defect occurs in the circuit board 1 or the electronic component 40 and the defective circuit board 1 or electronic component 40 is replaced, the circuit board 1 and the electronic component 40 are separated from each other by pulling out the pin 22 from the insertion port 41a. Further, when a defect occurs in the electronic component 30 mounted on the circuit board 1 of FIG. 2B and it is desired to remove the electronic component 40 before reworking the electronic component 30, the circuit board 1 and the electronic component 40 are separated from each other by pulling out the pin 22 from the insertion port 41a.

In the meantime, the pin 22 of the connection terminal 20 provided in the circuit board 1 has a material or an adjusted dimension so that the pin 22 may be bent to be inserted into the insertion port 41a of the connector 41 when the insertion port 41a is not aligned with the pin 22, and then the pin 22 may be restored to its original shape which is equal or similar to that of the pin 22 before the pin 22 is inserted when the pin 22 is pulled out from the insertion port 41a. As described above, when the pin 22 whose shape is restored is used, the pin 22 may be easily inserted again into the insertion port 41a of the connector 41.

Further, when being pulled out of the insertion port 41a, the pin 22 may not be restored but deformed (into a shape which is equal or similar to that of the pin 22 when the pin 22 is inserted) from its original shape which is the shape before the pin 22 is inserted. Thus, the pin 22 may be formed of a deformable material and have a dimension that allows the deformation as described above. Even the above-described pin 22 may be inserted into the same insertion port 41a of the connector 41 again and also may be inserted into the insertion port 41a of the connector 41 again after the deformed shape of the pin 22 is corrected to be the original shape.

Next, a second embodiment will be described.

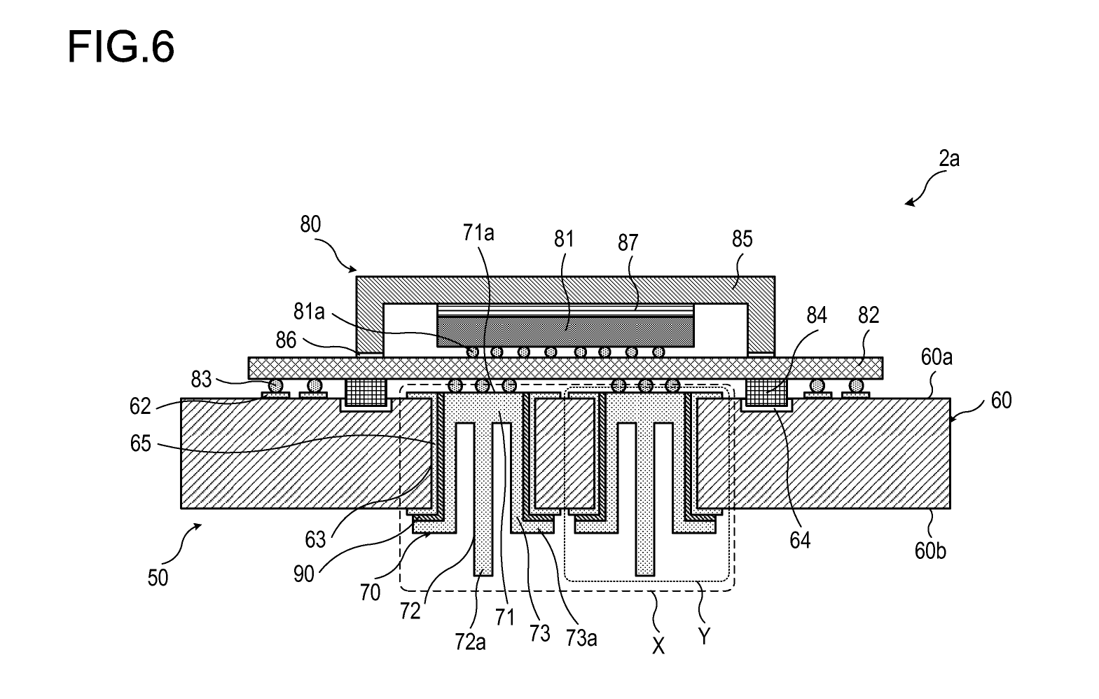

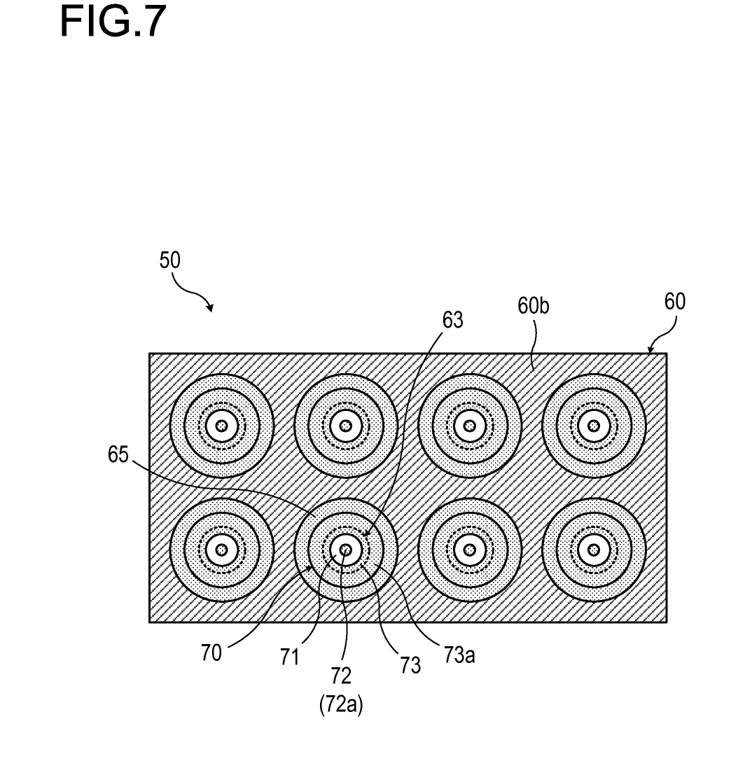

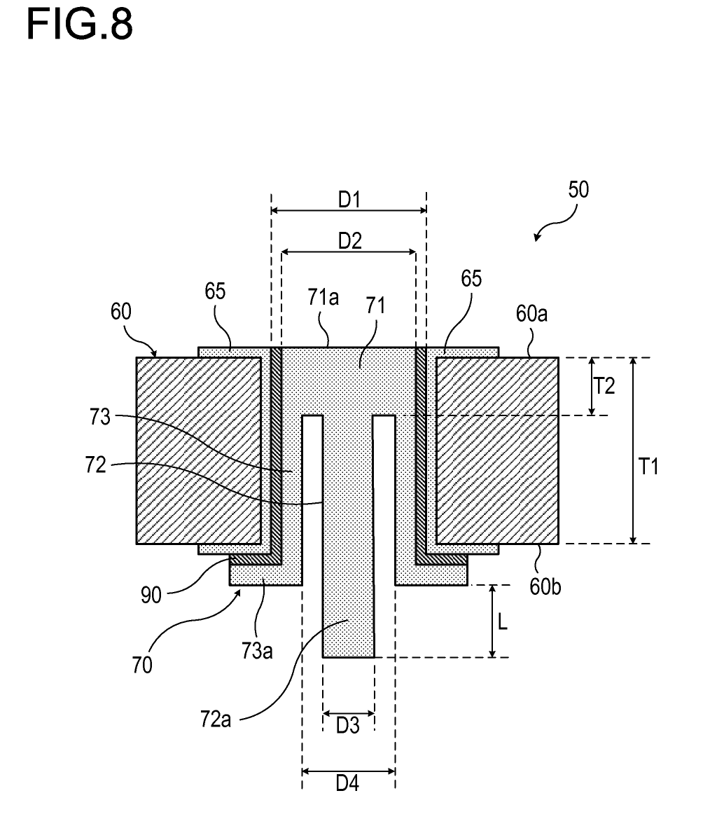

FIGS. 6 to 8 are views illustrating an example of a component-mounted circuit board according to a second embodiment. FIG. 6 schematically illustrates a cross-section of a main part of an example of the component-mounted circuit board according to the second embodiment. FIG. 7 illustrates a schematic plan view of an X portion (a connection terminal arrangement area) of FIG. 6 and FIG. 8 illustrates a schematic view of a Y portion (a connection terminal) of FIG. 6 in an enlarged scale.

A component-mounted circuit board 2a illustrated in FIG. 6 includes a system board 50 which is a circuit board and a semiconductor package 80 which is an electronic component mounted on the system board 50.

As illustrated in FIG. 6, the semiconductor package 80 includes a semiconductor chip 81 and a package substrate 82 which is a circuit board mounted with the semiconductor chip 81.

The semiconductor chip 81 is electrically connected to the package substrate 82, for example, using bumps 81a (terminals) by flip-chip bonding. Here, even though one semiconductor chip 81 is exemplified, one or more other semiconductor chips may be mounted on the package substrate 82, in addition to the semiconductor chip 81. Further, on the package substrate 82, in addition to the semiconductor chip 81, other electronic components, for example, a chip component such as a chip capacitor may be mounted.

A plurality of bumps 83 (terminals) is formed on a surface of the package substrate 82 which is opposite to a surface mounted with the semiconductor chip 81. For example, solder bumps such as solder balls may be used for the bumps 83. Even though the solder bump is exemplified here, a columnar electrode (pillar) using Cu, Ni, or Au may be used for the bumps 83. The package substrate 82 includes a conductor portion (a wiring or a via) on front and rear surfaces and inside thereof. The conductor portion electrically connects the mounted semiconductor chip 81 and the bumps 83 to each other.

An electronic component 84 such as, for example, a chip component such as a chip capacitor, is mounted on a surface of the package substrate 82 which is opposite to the surface mounted with the semiconductor chip 81, together with the bumps 83.

A lid 85 which covers the mounted semiconductor chip 81 is provided on the surface of the package substrate 82 mounted with the semiconductor chip 81. A material having a predetermined heat conductivity such as metal is used for the lid 85. An end portion of the lid 85 is fixed to the package substrate 82 using a bonding layer 86, and the lid 85 and the semiconductor chip 81 are bonded to each other using a bonding layer 87 having a predetermined heat conductivity such as a thermal interface material (TIM). The lid 85 serves not only to protect the semiconductor chip 81 but also serves as a heat radiating member (a heat sink) which radiates heat which is generated when the semiconductor chip 81 operates to the outside.

A printed board may be used for the system board 50 illustrated in FIGS. 6 to 8. The system board 50, as illustrated in FIGS. 6 to 8, includes a substrate 60 having a through hole 63 and a connection terminal 70 provided in the through hole 63.

The substrate 60 includes a conductor portion (a wiring and a via) which is provided on a front surface 60a, a rear surface 60b, and inside thereof and an insulating portion which is provided around the conductor portion. In FIG. 6, a conductor portion (a wiring) 62 provided on the front surface 60a of the substrate 60 is illustrated. In a position of the substrate 60 corresponding to the electronic component 84, for example, a concave portion 64 to be described later is formed. In the concave portion 64, a part of the electronic component 84 is accommodated when the semiconductor package 80 is mounted on the system board 50 through the bumps 83.

The through hole 63 is formed so as to penetrate between the front surface 60a and the rear surface 60b of the substrate 60. Further, in the example of FIG. 6, two through holes 63 are illustrated as seen from a cross-section, and in the example of FIG. 7, eight through holes 63 are illustrated as seen from a plan view. A planar shape (an opening shape) of each of the through holes 63 is, for example, a circle or substantially a circle.

As illustrated in FIGS. 6 and 8, a conductor layer 65 is formed on an inner wall of each of the through holes 63 of the substrate 60. The conductor layer 65 extends to outer peripheries of the through hole 63 at the front surface 60a and the rear surface 60b of the substrate 60. The conductor layer 65 is configured to be a through hole portion which provides conduction between the front surface 60a and the rear surface 60b of the substrate 60.

A plurality of connection terminals 70 is provided on the system board 50, as illustrated in FIGS. 6 and 7. Each of the connection terminals 70, as illustrated in FIGS. 6 to 8, includes a pedestal portion 71 having a predetermined thickness, a pin 72 provided at a center of the pedestal portion 71, and a side wall portion 73 provided at a periphery of the pedestal portion 71.

Various conductive materials may be used for the pedestal portion 71, the pin 72, and the side wall portion 73. Examples of conductive materials used for the pedestal portion 71, the pin 72, and the side wall portion 73 include metal materials such as Cu, Al, Au, Ag, or Ni. The pedestal portion 71, the pin 72, and the side wall portion 73 include one or more kinds of the metal materials. For example, the pedestal portion 71, the pin 72, and the side wall portion 73 may be formed of Cu and a separate metal film such as Au or solder may be formed on surfaces thereof. Further, the pedestal portion 71, the pin 72, and the side wall portion 73 may be formed of an alloy containing several kinds of metals.

The pedestal portion 71 has a planar shape which corresponds to a shape of an opening of the through hole 63 of the substrate 60, for example, as illustrated in FIG. 7, a circular shape or a substantially circular shape. A thickness of the pedestal portion 71 is set to be smaller than a thickness (a length in an axial direction of the through hole 63) of the substrate 60. The pedestal portion 71 having the thickness as described above is provided so as to be located inside the through hole 63.

The pin 72 has a planar size (a diameter) which is smaller than a planar size (a diameter) of the pedestal portion 71 and is provided so as to extend from the pedestal portion 71 to the rear surface 60b of the substrate 60. A length of the pin 72 is set such that a distal portion 72a in a direction extending from the pedestal portion 71 protrudes from the rear surface 60b of the substrate 60 and the conductor layer 65 on the rear surface 60b. The pin 72 is connected to the pedestal portion 71 which is located inside the through hole 63 at a base portion side opposite to the distal portion 72a and extends to the rear surface 60b of the substrate 60 in the through hole 63, so that the distal portion 72a protrudes from the rear surface 60b and the conductor layer 65 on the rear surface 60b. The pin 72 has a length and a diameter which allow flexibility such that the distal portion 72a is bent with the base portion continued to the pedestal portion 71 as a fulcrum point.

The length of the distal portion 72a of the pin 72 protruding from the rear surface 60b of the substrate 60 and the conductor layer 65 on the rear surface 60b is set based on, for example, a dimension (depth) of an insertion port (terminal) of a connection counterpart side into which the pin 72 is inserted and a distance (a gap) between the system board 50 and the connection counterpart after the system board 50 and the connection counterpart are connected to each other. The pin 72 has a structure in which the pin 72 extends in the through hole 63 (from the pedestal portion 71 provided inside the through hole 63) so as to secure a length which allows the flexibility. A thickness of the pedestal portion 71 provided inside the through hole 63 is set based on the thickness of the substrate 60 and the length and the diameter of the pin 72.

The side wall portion 73 is provided at the periphery of the pedestal portion 71 of which the central portion is connected to the pin 72. In the through hole 63, the side wall portion 73 and the pin 72 are provided apart from each other with a predetermined gap so that an inner surface of the side wall portion 73 is spaced apart from an outer surface of the pin 72. Similarly to the pin 72, the side wall portion 73 is provided so as to extend from the pedestal portion 71 toward the rear surface 60b of the substrate 60. The side wall portion 73 has a flange 73a at an end portion which is outwardly drawn from the rear surface 60b. The flange 73a faces the conductor layer 65 which extends to the rear surface 60b. The side wall portion 73 (and the flange 73a thereof) is provided over the entire periphery of the pedestal portion 71 so as to enclose the pin 72.

A size of the connection terminal 70 is set such that the connection terminal 70 is inserted into a region further inside than the conductor layer 65 provided on the inner wall of the through hole 63 of the substrate 60. For example, the size is set such that a predetermined gap is present between the outer surface of the side wall portion 73 and the inner surface of the conductor layer 65 as illustrated in FIG. 8. In an example of FIG. 8, a bonding layer 90 is formed at the gap between the outer surface of the side wall portion 73 and the inner surface of the conductor layer 65 provided on the inner wall of the through hole 63, and the connection terminal 70 is bonded to the conductor layer 65 of the substrate 60 through the bonding layer 90.

When the connection terminal 70 and the conductor layer 65 are electrically connected to each other, a conductive bonding material, such as solder, a solder-containing resin composition (a solder paste), or a resin composition containing a conductive material such as Ag (a conductive paste), may be used for the bonding layer 90. Further, when there is no need to necessarily electrically connect the connection terminal 70 and the conductor layer 65 to each other, an insulating resin material may be used for the bonding layer 90.

A position of a front surface 71a of the pedestal portion 71 of the connection terminal 70 which is bonded using the bonding layer 90 as described above is adjusted to a predetermined position, for example, a position to be bonded to the bumps 83 of the semiconductor package 80. The bonding layer 90 may be provided between the conductor layer 65 extending to the rear surface 60b of the substrate 60 and the flange 73a of the side wall portion 73 of the connection terminal 70, as illustrated in an example of FIG. 8. Since a gap is provided so that the bonding layer 90 is interposed between the connection terminal 70 and the conductor layer 65, the connection terminal 70 may be adjusted to a desired position to be fixed.

As an example, when the thickness T1 of the substrate 60 of the system board 50 is 3 mm, a diameter (a diameter of the through hole portion) D1 of a region further inside than the conductor layer 65 provided on the inner wall of the through hole 63 may be 6.2 mm. In this case, the connection terminal 70 may be set such that a diameter D2 of the pedestal portion 71 is 6 mm, a diameter D3 of the pin 72 is 4 mm, and a diameter D4 of the inner surface of the side wall portion 73 is 5 mm. A thickness T2 of the pedestal portion 71 of the connection terminal 70 may be 1 mm and a length L of the distal portion 72a of the pin 72 which protrudes from the flange 73a of the side wall portion 73 may be 2 mm.

The semiconductor package 80 is mounted on the system board 50 having the above-described configuration, as illustrated in FIG. 6. The semiconductor package 80 is disposed such that an arrangement surface side of the bumps 83 faces the front surface 60a of the system board 50, and then the semiconductor package 80 is electrically connected to the system board 50 through the bumps 83.

The bumps 83 provided in a partial region (an outer periphery in this example) of the semiconductor package 80 are bonded to the conductor portion 62 provided on the front surface 60a of the system board 50. The bumps 83 provided in another partial region (a center in this example) of the semiconductor package 80 are bonded to the front surface 71a of the pedestal portion 71 of each of the connection terminals 70 of the system board 50. The plurality of bumps 83 may be bonded to the front surface 71a of the pedestal portion 71 of each of the connection terminals 70, as illustrated in FIG. 6. The bumps 83 are directly bonded to the pedestal portion 71 so as to be bonded to the connection terminal 70 with a low resistance. However, instead of the plurality of bumps 83, a singular bump may be bonded to the front surface 71a of the pedestal portion 71 of each of the connection terminals 70.

Further, in this example, a part of the electronic component 84 of the semiconductor package 80 is accommodated in the concave portion 64 of the system board 50.

The component-mounted circuit board 2a having the system board 50 provided with the connection terminals 70 as illustrated in FIGS. 6 to 8 is mounted on, for example, a power supply board which is a circuit board which supplies power to the component-mounted circuit board 2a.

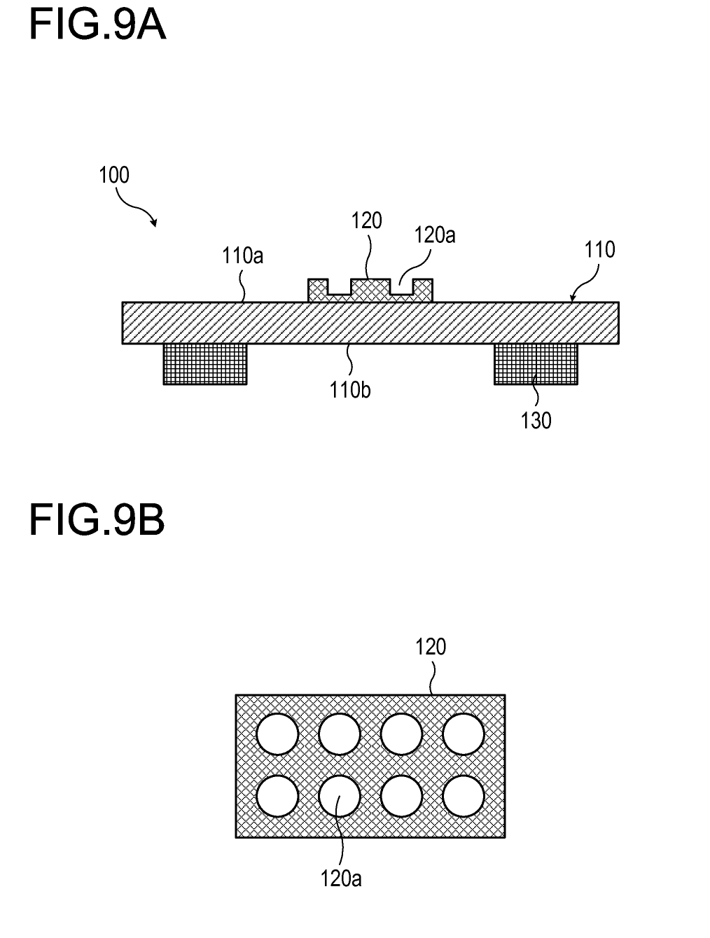

FIGS. 9A and 9B are views illustrating an example of a power supply board according to the second embodiment. FIG. 9A schematically illustrates a cross-section of a main part of an example of the power supply board according to the second embodiment and FIG. 9B schematically illustrates a plan view of a main part of an example of a connector provided in the power supply board according to the second embodiment.

A printed board may be used for a power supply board 100 illustrated in FIG. 9A. As illustrated in FIG. 9A, the power supply board 100 includes a substrate 110 and a connector 120 which is provided on a front surface 110a of the substrate 110. The power supply board 100 illustrated in FIG. 9A further includes various electronic components 130, such as a DC-DC converter, provided on a rear surface 110b of the substrate 110.

The connector 120 of the power supply board 100 is provided in a region corresponding to the arrangement region of the connection terminals 70 of the system board 50. The connector 120 includes insertion ports 120a into which the distal portions 72a of the pins 72 are inserted, at positions corresponding to the pins 72 of the connection terminals 70. Each of the insertion ports 120a of the connector 120 has a concave terminal structure which is electrically connected to an internal structure (a conductor portion such as a wiring or a via) of the power supply board 100. FIG. 9B illustrates the connector 120 having eight insertion ports 120a corresponding to eight pins 72 (see FIG. 7) of the connection terminals 70, as an example.

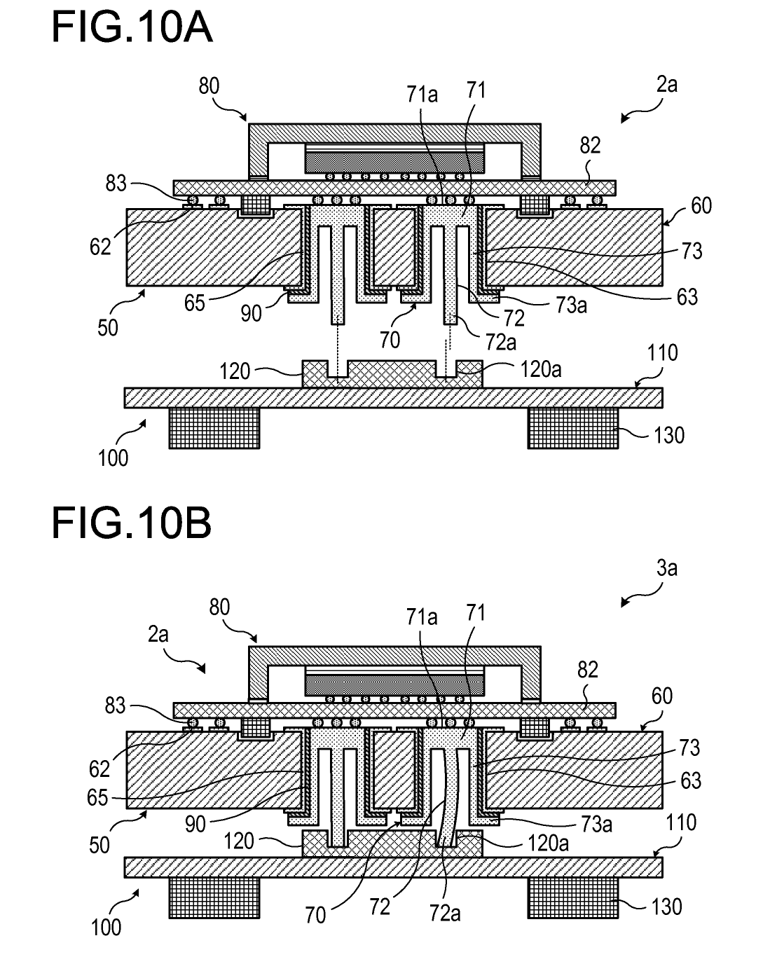

FIGS. 10A and 10B are views illustrating an example of a connecting process of a connection terminal and a connector according to the second embodiment. FIG. 10A schematically illustrates a cross-section of a main part of an example of the connection terminal and the connector according to the second embodiment before they are connected to each other and FIG. 10B schematically illustrates a cross-section of a main part of an example of the connection terminal and the connector according to the second embodiment after they are connected to each other.

On the front surface 110a of the power supply board 100 (FIG. 9) provided with the connector 120, the component-mounted circuit board 2a (FIG. 6) is disposed such that the front surface 110a faces the system board 50. Further, the distal portions 72a of the pins 72 of the connection terminals 70 provided on the system board 50 are inserted into the insertion ports 120a of the connector 120 of the power supply board 100 to electrically connect the component-mounted circuit board 2a to the power supply board 100.

When each of the pins 72 is inserted, as illustrated in FIG. 10A, the position of the pin 72 and the position of each of the insertion ports 120a of the connector 120 may be misaligned (axial positions of the pin 72 and the insertion port 120a are indicated by dotted lines). Here, in the connection terminal 70 of the system board 50, the pin 72 is provided so as to extend from the pedestal portion 71 located inside the through hole 63 of the substrate 60 and the distal portion 72a thereof is configured to protrude to the rear surface 60b of the substrate 60, so that the pin 72 has flexibility. Therefore, even though the pin 72 and the insertion port 120a of the connector 120 are misaligned as illustrated in FIG. 10A, when the distal end of the pin 72 enters the insertion port 120a, the pin 72 is bent to be inserted into the insertion port 120a as illustrated in FIG. 10B. As described above, since the pin 72 is bent to be inserted into the insertion port 120a of the connector 120 to be connected to the connector 120, the system board 50 and the power supply board 100 are electrically connected.

The system board 50 of the component-mounted circuit board 2a employs the connection terminal 70 configured such that the pin 72 has flexibility. Therefore, the distortion caused by misalignment between the pin 72 and the insertion port 120a is absorbed and thus stress is suppressed from occurring, thereby obtaining a component-mounted circuit board 3a having high connection reliability.

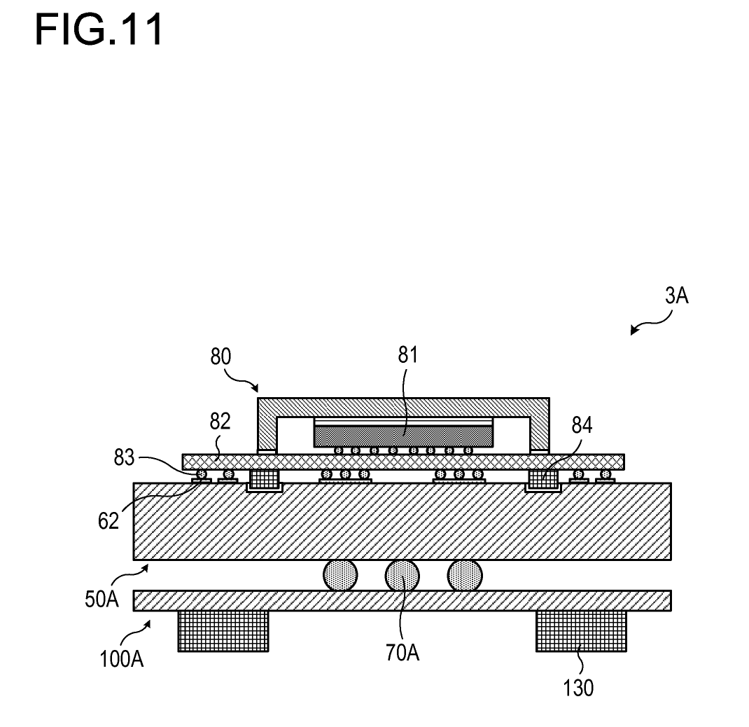

Here, FIGS. 11 to 13 are views illustrating an example of a component-mounted circuit board according to another embodiment. FIGS. 11 to 13 schematically illustrate cross-sections of main parts of examples of a component-mounted circuit board according to different embodiments, respectively.

A component-mounted circuit board 3A illustrated in FIG. 11 has a structure in which a system board 50A mounted with a semiconductor package 80 is electrically connected to a power supply board 100A using solder bumps 70A. Further, there may be a structure that, instead of the solder bumps 70A, a filler such as Cu is soldered to electrically connect the system board 50A to the power supply board 100A.

In the component-mounted circuit board 3A, when a defect occurs in the semiconductor package 80 (for example, a semiconductor chip 81) after the system board 50A mounted with the semiconductor package 80 is connected to the power supply board 100A, it is advantageous to rework the semiconductor package 80 in view of cost in some cases. That is, the defective semiconductor package 80 is removed from the system board 50A and a no-defective semiconductor package is mounted on the system board 50A.

When the reworking is performed on the semiconductor package, heating is performed at a temperature at which the bumps 83 are melted in order to remove the defective semiconductor package 80 bonded to the system board 50A through the bumps 83. When the heating is performed, the power supply board 100A may be removed in advance in order to avoid influence on the power supply board 100A or incomplete bonding between the power supply board 100A and the system board 50A due to the heating.

However, when the power supply board 100A is removed in advance as described above, in addition to the heating at the time of reworking the semiconductor package 80, two times of extra heating is required to remove and attach the power supply board 100A. As a result, the number of rework processes is increased, a cost therefor is increased, and reliability of the solder bonding portion is lowered due to the increase of heat history.

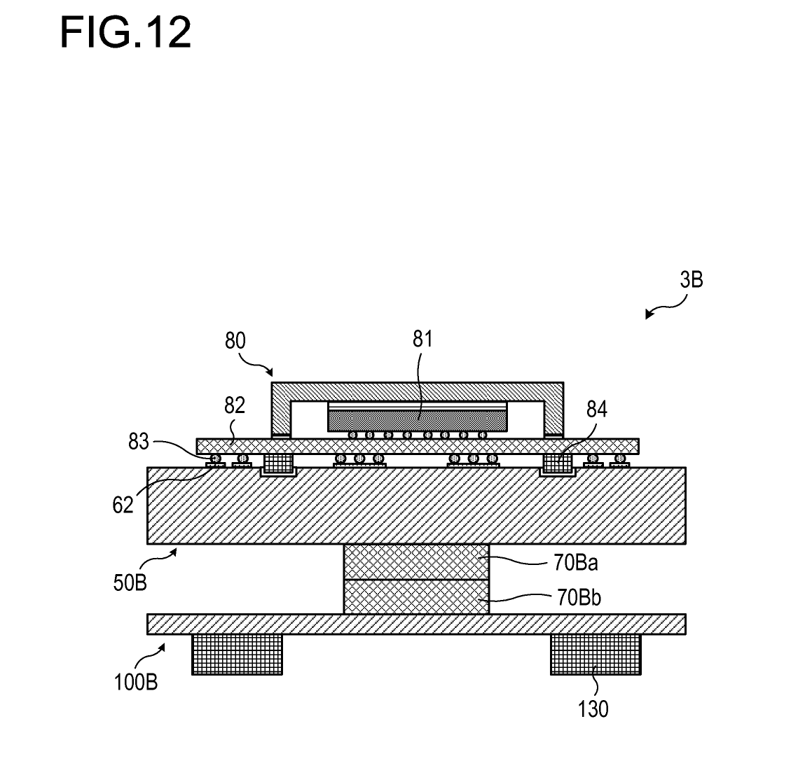

A component-mounted circuit board 3B illustrated in FIG. 12 has a structure in which a system board 50B mounted with a semiconductor package 80 is electrically connected to a power supply board 100B using two connectors 70Ba and 70Bb provided on opposite surfaces of the system board 50B and the power supply board 100B, so called staking connectors.

On the component-mounted circuit board 3B, the connectors 70Ba and 70Bb may be inserted to each other or removed from each other, so that the system board 50B and the power supply board 100B are attached to each other or detached from each other. Therefore, even when the reworking of the semiconductor package 80 is performed, the power supply board 100B may be relatively easily detached from the system board 50B before the reworking and may be relatively easily attached to the system board 50B after the reworking.

However, since the two connectors 70Ba and 70Bb are relatively thicker than, for example, the bumps, the gap between the system board 50B and the power supply board 100B after being connected is increased, so that a size of the component-mounted circuit board 3B is increased. Further, the connecting distance between the system board 50B and the power supply board 100B is increased, so that a power drop may be increased.

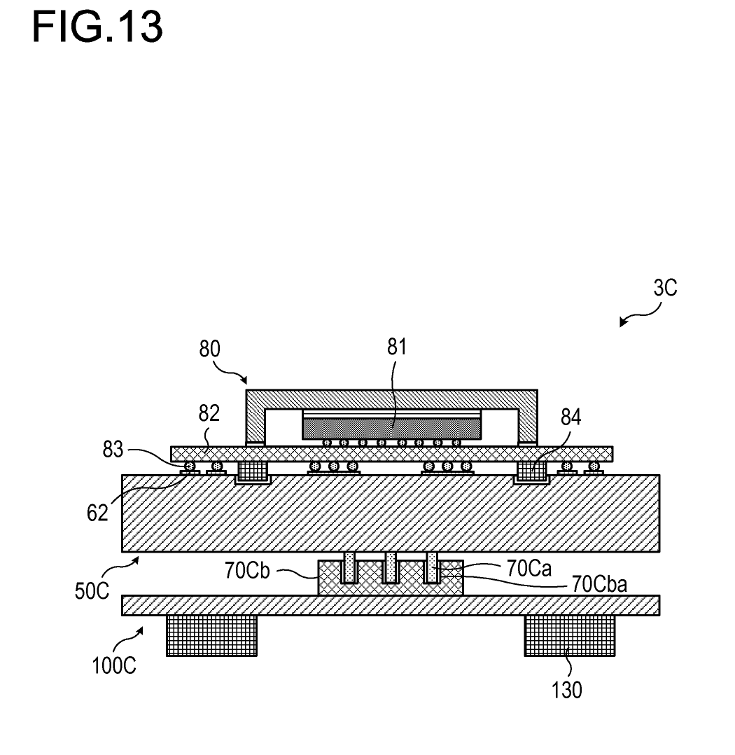

A component-mounted circuit board 3C illustrated in FIG. 13 has a structure in which pins 70Ca are provided at a system board 50C side and a connector 70Cb having insertion ports 70Cba of the pins 70Ca is provided at a power supply board 100C side. Each of the pins 70Ca is provided by soldering a pin made of, for example, Cu on the system board 50C.

In the component-mounted circuit board 3C, since the pins 70Ca and the connector 70Cb are used, the size increase is suppressed as compared with the component-mounted circuit board 3B using the two connectors 70Ba and 70Bb as described above.

However, in the component-mounted circuit board 3C, the pins 70Ca and the insertion ports 70Cba of the connector 70Cb which are connected to be each other may be misaligned in some cases. When any pin in the group of the pins 70Ca group is misaligned from the corresponding insertion port 70Cba, it may be difficult to smoothly insert all the pins 70Ca into the corresponding insertion ports 70Cba. Further, as illustrated in FIG. 4, when any one of the pins 70Ca is inserted into an insertion port 70Cba misaligned from the pin 70Ca, stress may occur in the pin 70Ca. Then, the pin 70Ca may be broken or the connection reliability may be lowered due to the stress.

In contrast, in the second embodiment, the system board 50 employs the connection terminal 70 having the pin 72 which is flexible and has the distal portion 72a protruding at the power supply board 100 side. In a case where the distal portion 72a of the pin 72 which is flexible is inserted into the insertion port 120a of the connector 120 of the power supply board 100 as illustrated in FIGS. 10A and 10B, even when the pin 72 is misaligned from the insertion port 120a, the distortion caused by misalignment is absorbed to suppress the stress from occurring. Accordingly, the component-mounted circuit board 3a having high connection reliability may be obtained. Even when the connection terminal 70 is disposed with a precision which causes misalignment between the pin 72 and the insertion port 120a of the connector 120, it can be said that the through hole 63 may be formed in the substrate 60.

In the component-mounted circuit board 3a, when the power supply board 100 is removed during reworking of the semiconductor package 80, the pins 72 of the connection terminals 70 at the system board 50 side may be pulled out from the insertion ports 120a of the connector 120 at the power supply board 100 side to remove the power supply board 100. Therefore, there is no need to heat the power supply board 100 to attach and detach the power supply board 100.

Further, according to the above-described connection terminal 70, the length of the distal portion 72a of each of the pins 72 which protrudes to the power supply board 100 side may be adjusted, so that the gap between the system board 50 and the power supply board 100 may be narrowed as compared with a case where the connector is provided at the system board 50 side (see FIG. 12). Accordingly, a small-sized (thin) component-mounted circuit board 3a may be obtained.

Moreover, the pedestal portion 71 and the pin 72 which extends from the pedestal portion 71 become a major conducting path between the front surface and the rear surface in the connection terminal 70. Therefore, as compared with a case where the through hole portion having the conductor layer 65 provided on the inner wall of the through hole 63 solely serves as the conducting path between the front surface and the rear surface, an area of the conducting path in the connection terminal 70 is increased, so that the conducting is stably performed and high current used for a power supply may be stably conducted.

The bumps 83 of the semiconductor package 80 may be directly bonded to the pedestal portion 71 of the connection terminal 70 and the bumps 83 and the connection terminal 70 may be bonded to each other with low resistance. Further, the pin 72 of the connection terminal 70 is connected to the pedestal portion 71 to be supported. Therefore, when the pedestal portion 71 is adjusted to have a predetermined thickness, distortion may be suppressed from occurring in the bonding portion between the pedestal portion 71 and the semiconductor package 80 even if the pin 72 continued to the pedestal portion 71 is bent when the connection terminal 70 and the connector 120 are connected to each other pedestal portion 71. Accordingly, the bumps 83 and the connection terminal 70 may be bonded to each other with high reliability.

Further, when the connection terminal 70 is fixed to the substrate 60 of the system board 50 using the bonding layer 90, the connection terminal 70 may be adjusted to a desired position to be solidly fixed. Accordingly, the bumps 83 and the pedestal portion 71 may be precisely connected to each other and the gap between the system board 50 and the power supply board 100 which is connected to the connection terminal 70 may be precisely adjusted.

Next, an example of a forming method for the connection terminal 70 as described above will be described.

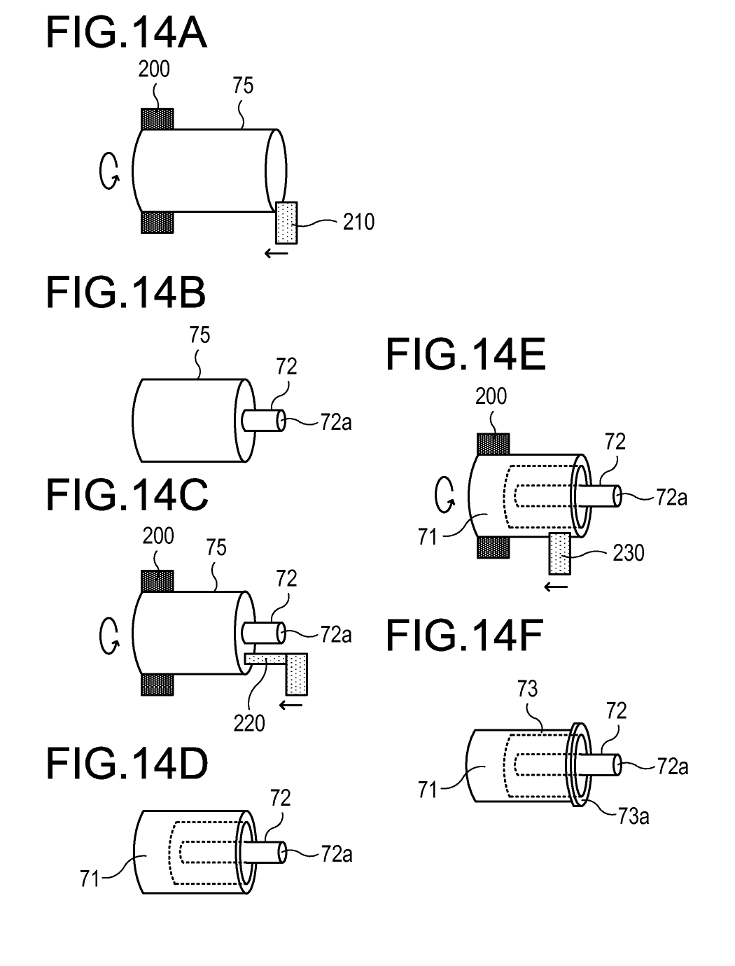

FIGS. 14A to 14F are views illustrating an example of a forming method of a connection terminal according to the second embodiment. Here, a forming method of the connection terminal 70 using a lathe machining will be exemplified.

First, as illustrated in FIG. 14A, a cylindrical conductor, for example, a cylindrical metal 75 made of Cu is prepared. The prepared metal 75 has a length and a diameter which correspond to the entire length (a length from a front surface 71a of a pedestal portion 71 to a distal end of a pin 72) and a diameter (an outer diameter of a flange 73a of a side wall portion 73) of the connection terminal 70 to be formed.

The prepared metal 75 is fixed to a chuck 200 and then the chuck 200 is rotated to cut an outer periphery of the metal 75 using a bite 210. In this case, the outer periphery of the metal 75 is cut by the bite 210 to have a length corresponding to a length of a protruding distal portion 72a of the pin 72 of the connection terminal 70 to be formed. Therefore, as illustrated in FIG. 14B, a part of the pin 72 of the connection terminal 70, that is, the distal portion 72a is formed.

Next, the metal 75 around the pin 72 (the distal portion 72a) is inwardly cut using an L-shaped bite 220 as illustrated in FIG. 14C while an outer wall remains. In that case, the metal 75 is inwardly cut to have a depth corresponding to the length of the pin 72 of the connection terminal 70 to be formed. Therefore, as illustrated in FIG. 14D, the pin 72 and the pedestal portion 71 of the connection terminal 70 pedestal portion 71 are formed.

Next, as illustrated in FIG. 14E, an outer periphery of the metal 75 is cut using a bite 230 while a wall which encloses a portion corresponding to the pin 72 remains. Therefore, as illustrated in FIG. 14F, the side wall portion 73 of the connection terminal 70 and the flange 73a are formed.

The connection terminal 70 including the pedestal portion 71, the pin 72, and the side wall portion 73 is formed by the above-mentioned process.

In the meantime, as the metal 75 to be prepared, a cylindrical rod material having a length equal to or greater than the entire length (a length from the front surface 71a of the pedestal portion 71 to the distal end of the pin 72) of the connection terminal 70 to be formed may be prepared and the steps illustrated in FIGS. 14A to 14F may be performed on a distal portion of the cylindrical rod material. In this case, after a structure corresponding to the connection terminal 70 is formed in the distal portion of the rod material, the distal portion of the rod material formed with the structure is cut out at a position having a length corresponding to the entire length of the connection terminal 70.

Further, a surface of the connection terminal 70 which is formed by performing the steps as illustrated in FIGS. 14A to 14F may be covered with a metal layer such as Au or solder. When the solder is used for the bonding layer 90 described above to fix the connection terminal 70, the surface of the connection terminal 70 may be covered with Au since Au has good wettability with the solder so that the connection terminal 70 may be solidly fixed. Further, when the surface of the connection terminal 70 is covered with the solder, the solder may be used as the bonding layer 90 or a part of the bonding layer 90 and also used as a part of a bonding material with the bumps 83 of the semiconductor package 80.

Next, an example of a forming method of the system board 50 using the connection terminal 70 and an example of a forming method of the component-mounted circuit board 2a including the system board 50 using the connection terminal 70 will be described.

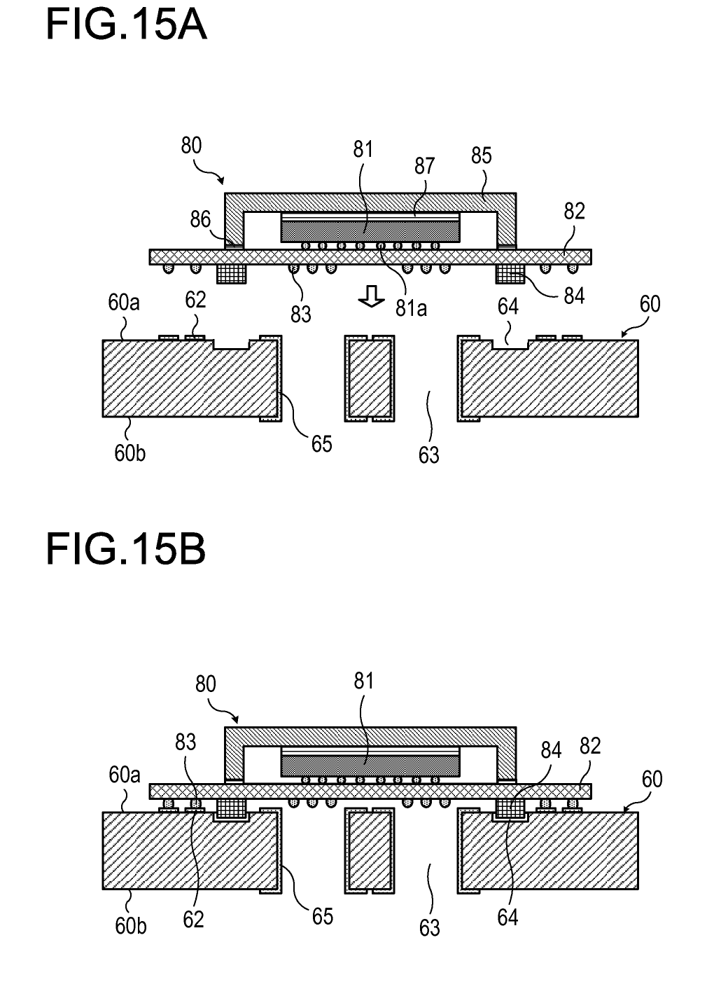

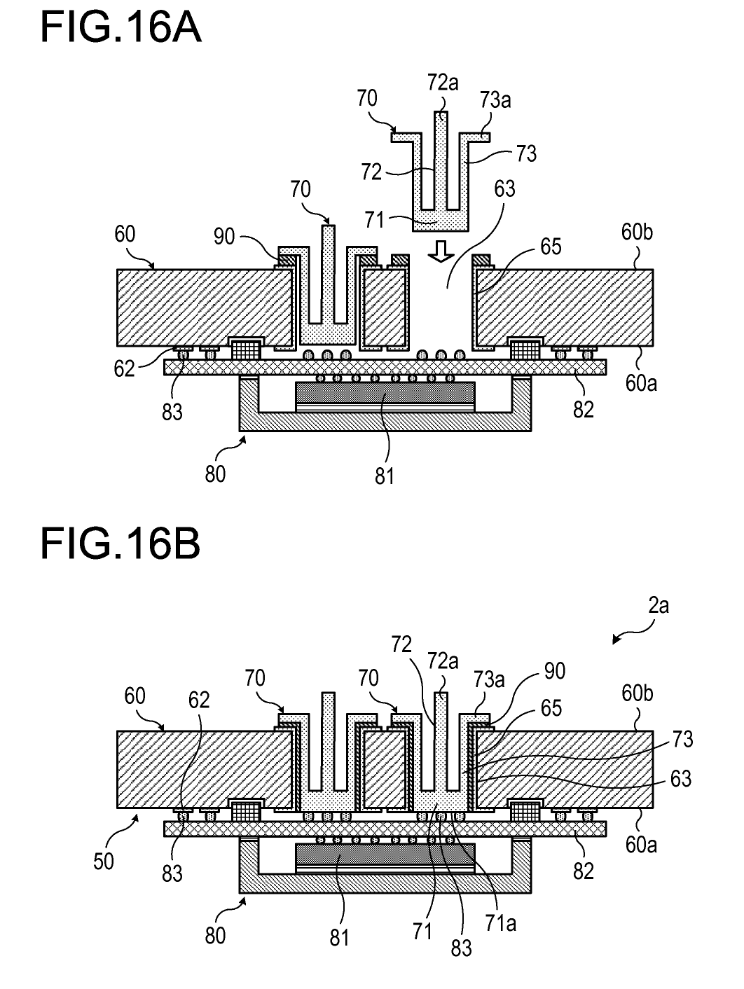

FIGS. 15A to 16B are views illustrating an example of a manufacturing method of a component-mounted circuit board according to the second embodiment. FIG. 15A schematically illustrates a cross-section of a main part of an example before the semiconductor package is connected and FIG. 15B schematically illustrates a cross-section of a main part of an example after the semiconductor package is connected. FIG. 16A schematically illustrates a cross-section of a main part of an example before the connection terminal is arranged and FIG. 16B schematically illustrates a cross-section of a main part of an example after the connection terminal is arranged.

A connection terminal 70 is provided in a through hole 63 of a substrate 60 formed with a conductor layer 65 in a system board 50.

In this example, first, as illustrated in FIG. 15A, the substrate 60 is prepared. The substrate 60 has a conductor portion (a conductor portion 62 on a front surface 60a is illustrated here) such as a wiring or a via which is formed on front and rear surfaces and inside thereof, and the conductor layer 65 formed on an inner wall of the through hole 63. Further, together with the substrate 60, a semiconductor package 80 to be mounted on the substrate 60 is prepared.

In the meantime, the substrate 60 may be formed using a buildup technique and obtained by forming the through hole 63 by performing a punching process using a drill after forming a laminated body including the conductor portion and then forming the conductor layer 65 on the inner wall of the through hole 63 using a plating method. The semiconductor package 80 is obtained by flip-chip bonding a semiconductor chip 81 onto a package substrate 82 using, for example, bumps 81a and then attaching a lid 85 through bonding layers 86 and 87, attaching the bumps 83, and attaching an electronic component 84.

After the substrate 60 and the semiconductor package 80 are prepared, as illustrated in FIG. 15A, the prepared substrate 60 and semiconductor package 80 are disposed such that the front surface 60a faces the arrangement surface of the bumps 83.

Next, as illustrated in FIG. 15B, the conductor portion 62 of the front surface 60a of the substrate 60 is bonded to the bumps 83 in a part (an outer periphery) of the semiconductor package 80. For example, under an inert gas atmosphere such as nitrogen (N₂), heating is performed at a temperature at which the bumps 83 are melted to bond the conductor portion 62 with the corresponding bumps 83.

In the substrate 60 mounted with the semiconductor package 80 as described above, the connection terminal 70 is inserted into the through hole 63 formed with the conductor layer 65 from the rear surface 60b side which is opposite to the semiconductor package 80 side, as illustrated in FIG. 16A. In this case, a bonding layer 90 such as solder is disposed on the conductor layer 65 on the rear surface 60b and the connection terminal 70 is inserted into the through hole 63 formed with the conductor layer 65 from the pedestal portion 71. At the time of insertion, a side wall portion 73 serves as a guide, so that the connection terminal 70 inserted into the through hole 63 of the substrate 60 is suppressed from being significantly oblique. Further, since a flange 73a is formed on the side wall portion 73, the connection terminal 70 may be more securely avoided being inserted into the semiconductor package 80 from the position where the flange 73a comes in contact with the conductor layer 65 on the rear surface 60b.

After the connection terminal 70 is inserted, under the inert gas atmosphere, heating is performed at a temperature at which the bonding layer 90 and the bumps 83 are melted, and as illustrated in FIG. 16B, the front surface 71a of the pedestal portion 71 of the inserted connection terminal 70 is bonded while being in contact with the bumps 83 corresponding to a region of the through hole 63. Since the bonding layer 90 is interposed between the connection terminal 70 and the conductor layer 65, the connection terminal 70 may be appropriately adjusted to a position where the front surface 71a of the pedestal portion 71 is bonded to the bumps 83.

By the methods as illustrated in FIGS. 15A and 15B and FIGS. 16A and 16B, the system board 50 using the connection terminal 70, and the component-mounted circuit board 2a including the system board 50 using the connection terminal 70 are formed.

Here, in the exemplified method, the semiconductor package 80 is mounted on the substrate 60 before the connection terminal 70 is inserted, and then the connection terminal 70 is inserted into the substrate 60.

In addition, a method of mounting the semiconductor package 80 on the system board 50 after completing the system board 50 by inserting the connection terminal 70 into the substrate 60 first may also be employed. According to this method, first, the substrate 60 is prepared in which the conductor portion is formed on the front surface, the rear surface and inside the substrate 60, and the conductor layer 65 is formed on the inner wall of the through hole 63. Further, the bonding layer 90 such as solder is disposed on the conductor layer 65 on the rear surface 60b of the substrate 60 and the connection terminal 70 is inserted into the through hole 63 formed with the conductor layer 65, from the pedestal portion 71. Thereafter, under the inert gas atmosphere, heating is performed at a temperature at which the bonding layer 90 is melted to fix the pedestal portion 71 to the substrate 60 such that the front surface 71a of the pedestal portion 71 is adjusted in accordance with a predetermined position to be aligned with the surface of the conductor layer 65 on the rear surface 60b. By doing this, the system board 50 is completed first. Further, the semiconductor package 80 is disposed at the front surface 60a side of the completed system board 50 such that the semiconductor package 80 faces the arrangement surface side of the bumps 83, and the bumps 83 are bonded to the conductor portion 62 of the front surface 60a of the system board 50 and the front surface 71a of the pedestal portion 71 to obtain the component-mounted circuit board 2a.

In the meantime, the flange 73a of the side wall portion 73 of the connection terminal 70 does not need to be necessarily provided as long as the connection terminal 70 can be disposed at a predetermined position when the connection terminal 70 is inserted into the through hole 63 of the substrate 60.

Hereinafter, modified embodiments will be described.

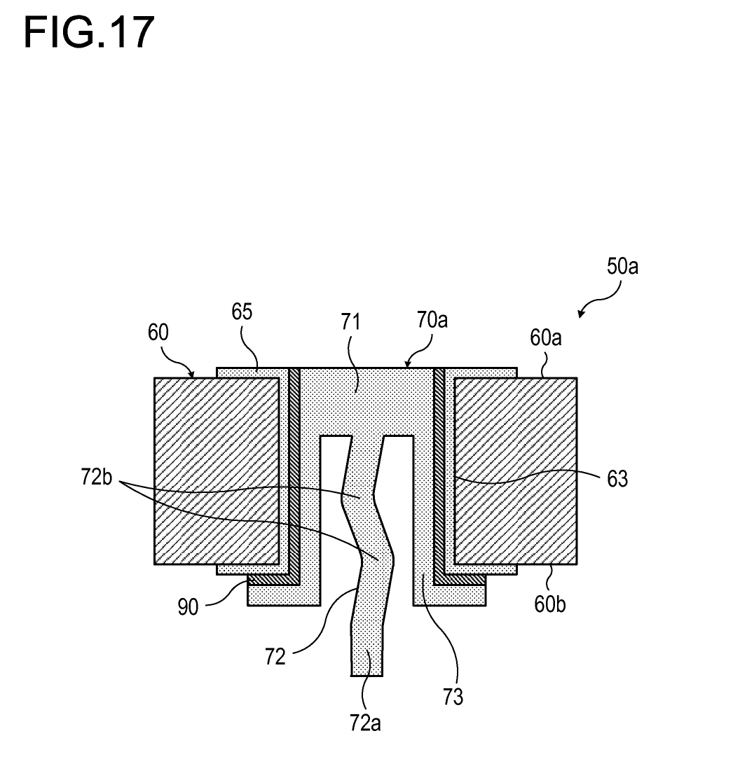

FIG. 17 is an explanatory view of a first modified embodiment. FIG. 17 schematically illustrates a cross-section of a main part of a system board including a connection terminal according to a first modified embodiment.

A system board 50a illustrated in FIG. 17 is different from the system board 50 provided with the above-described connection terminal 70 in that the system board 50a is provided with a connection terminal 70a having a curved or bent bending portion 72b in a part of the pin 72.

The pin 72 having the bending portion 72b may be formed, for example, by pressing the pin 72 formed as illustrated in FIG. 14 from the distal portion 72a side to the base portion side (the pedestal portion 71 side). When the bending portion 72b is formed in the pin 72, the pin 72 may be more flexible as compared with the straight pin 72 as described above.

Even when the pin 72 is misaligned from the insertion port 120a of the connector 120, the distortion caused by the misalignment is efficiently absorbed by the pin 72 having the bending portion 72b which is inserted into the insertion port 120a, thereby suppressing stress from occurring. Then, the component-mounted circuit board having high connection reliability may be obtained.

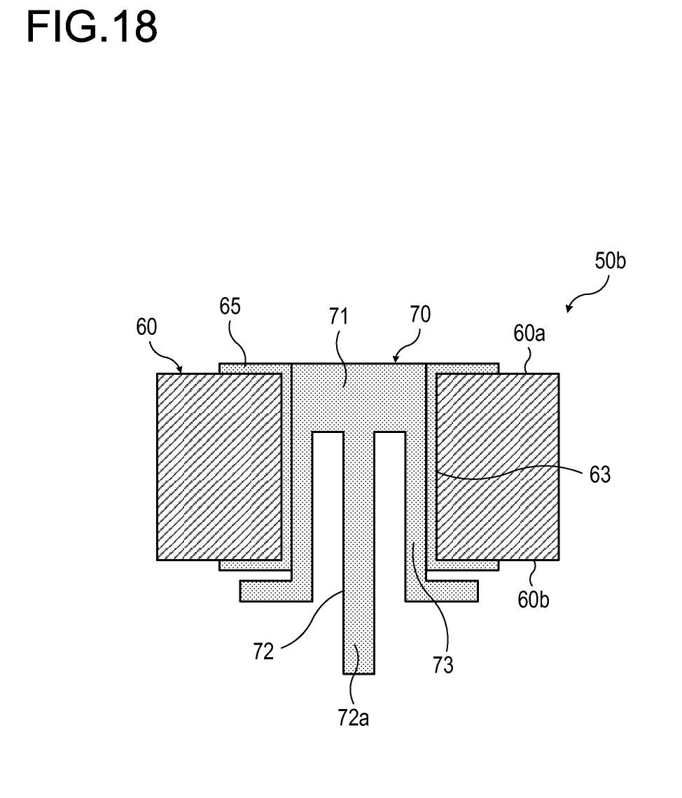

FIG. 18 is an explanatory view of a second modified embodiment. FIG. 18 schematically illustrates a cross-section of a main part of a system board including a connection terminal according to the second modified embodiment.

A system board 50b illustrated in FIG. 18 is different from the system board 50 in which the connection terminal 70 is fixed using the above-described bonding layer 90, in that the connection terminal 70 is fitted into the through hole 63 formed with the conductor layer 65 in the substrate 60.

In the system board 50b, an inner surface of the conductor layer 65 in the through hole 63 is in direct contact with an outer surface of the side wall portion 73 of the connection terminal 70 without having the above-described bonding layer 90 therebetween. Further, the bonding layer 90 does not need to be provided between the conductor layer 65 on the rear surface 60b and the flange 73a of the side wall portion 73.

The system board 50b may be formed while a material used for the bonding layer 90 is reduced, and the component-mounted circuit board may be obtained using such a system board 50b.

In the meantime, the connection terminal 70a including the pin 72 having the bending portion 72b described in the first modified embodiment may be fitted into the through hole 63 formed with the conductor layer 65 in the substrate 60 as in the second modified embodiment, thereby obtaining the system board.

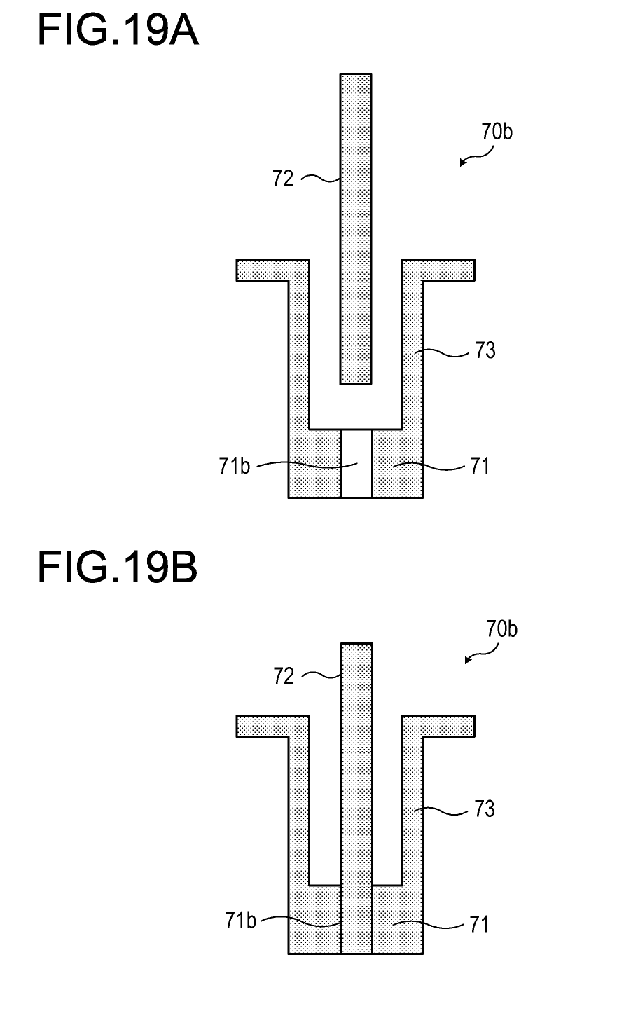

FIGS. 19A and 19B are explanatory views of a third modified embodiment. FIGS. 19A and 19B schematically illustrate a cross-section of a main part of a connection terminal according to the third modified embodiment before and after the connection terminal is assembled.

A connection terminal 70b illustrated in FIGS. 19A and 19B includes a pedestal portion 71 having a hole 71b at a center thereof and a pin 72 which is inserted into the hole 71b of the pedestal portion 71. The pedestal portion 71 and a side wall portion 73 may be integrally configured.

As illustrated in FIG. 19A, the pedestal portion 71 having the side wall portion 73 at a periphery thereof, and pedestal portion 71 the hole 71b at a center thereof, and the pin 72 which is connected to the pedestal portion 71 are prepared, and as illustrated in FIG. 19B, the pin 72 is fitted into the hole 71b of the pedestal portion 71 to obtain the connection terminal 70b. The hole 71b may be a through hole which penetrates the pedestal portion 71 as illustrated in FIGS. 19A and 19B or may be a concave portion having a bottom which does not penetrate the pedestal portion 71.

It is comparatively easy to separately form a structure in which the pedestal portion 71 and the side wall portion 73 are integrated, and the pin 72, as compared with a case where a structure in which the pedestal portion 71, the pin 72, and the side wall portion 73 are integrated is cut, as in the above-described connection terminal 70. The connection terminal 70b may be obtained using a simpler forming method and a system board using the connection terminal 70b obtained as described above and the component-mounted circuit board may be further obtained.

In the meantime, when the system board is obtained using the connection terminal 70b described in the third modified embodiment, the connection terminal 70b may be not only inserted into the through hole 63 of the substrate 60 using the bonding layer 90, but also fitted into the through hole 63 as described in the second modified embodiment. Further, the pin 72 having the bending portion 72b as described in the first modified embodiment may be inserted into the pedestal portion 71 having the hole 71b which has been described in the third modified embodiment, thereby obtaining the connection terminal.

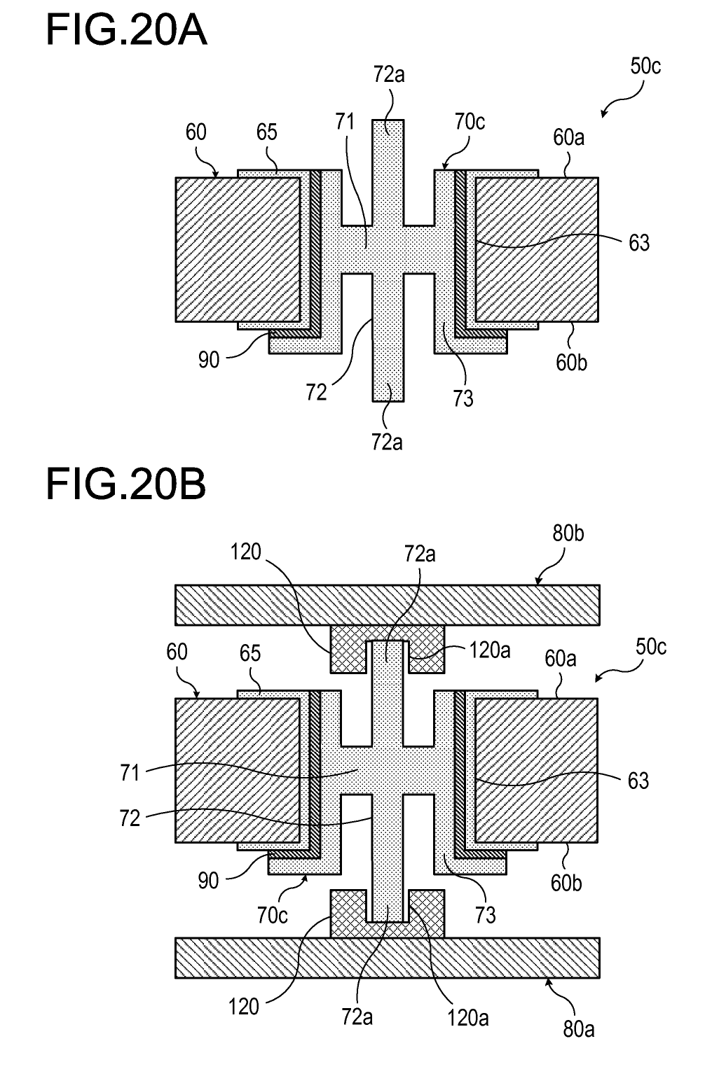

FIGS. 20A and 20B are explanatory views of a fourth modified embodiment. FIG. 20A schematically illustrates a cross-section of a main part of a system board including a connection terminal according to the fourth modified embodiment and FIG. 20B schematically illustrates a cross-section of a main part of a component-mounted circuit board according to the fourth modified embodiment.

A system board 50c illustrated in FIG. 20A includes a connection terminal 70c having a pin 72 which protrudes toward both a front surface 60a and a rear surface 60b of a substrate 60, from a pedestal portion 71 located inside a through hole 63. As illustrated in FIG. 20B, a connector 120 of a first electronic component 80a is connected to a distal portion 72a of the pin 72 which protrudes toward the rear surface 60b of the system board 50c and a connector 120 of a second electronic component 80b is connected to a distal portion 72a of the pin 72 which protrudes toward the front surface 60a of the system board 50c.

The system board 50c as described above may be connected to the electronic component 80a and the electronic component 80b each including the connector 120 while stress caused by the misalignment between the pin 72 and the connector 120 is suppressed from occurring, thereby obtaining the component-mounted circuit board having high connection reliability.

Further, the bending portion 72b as described in the first modified embodiment may be formed in the pin 72 of the connection terminal 70c described in the fourth modified embodiment. Further, the connection terminal 70c described in the fourth modified embodiment may be fitted into the through hole 63 of the substrate 60 as in the second modified embodiment. Moreover, the connection terminal 70c described in the fourth modified embodiment may have a structure in which the pedestal portion 71 having the hole 71b at the center thereof and the side wall portion 73 are integrated and the pin 72 is inserted into the hole 71b, as in the third modified embodiment.

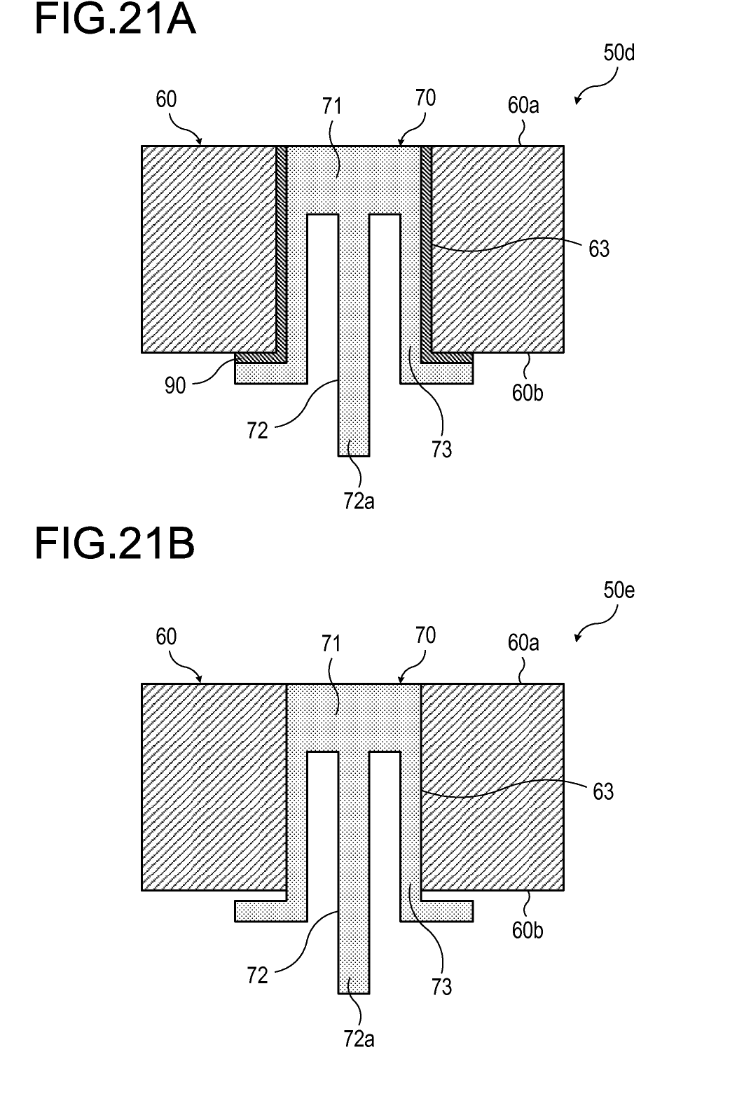

FIGS. 21A and 21B are explanatory views of a fifth modified embodiment. FIG. 21A schematically illustrates a cross-section of a main part of a first example of a system board including a connection terminal according to the fifth modified embodiment and FIG. 21B schematically illustrates a cross-section of a main part of a second example of a system board including a connection terminal according to the fifth modified embodiment.

A system board 50d illustrated in FIG. 21A has a structure in which a connection terminal 70 is inserted in a through hole 63 which does not have the conductor layer 65 as described above on an inner wall and is fixed using a bonding layer 90 made of conductive or insulating resin.

Further, a system board 50e illustrated in FIG. 21B has a structure in which a connection terminal 70 is fitted into a through hole 63 which does not have the conductor layer 65 as described above on an inner wall, without using a bonding layer 90.

The system board 50d and the system board 50e may also be connected to the power supply board 100 while suppressing the stress caused by the misalignment between the pin 72 and the connector 120 from occurring, thereby obtaining the component-mounted circuit board having high connection reliability.

Further, the bending portion 72b as described in the first modified embodiment may be formed in the pin 72 of the connection terminal 70 described in the fifth modified embodiment. Further, the connection terminal 70 described in the fifth modified embodiment may have a structure in which the pedestal portion 71 having the hole 71b at the center thereof and the side wall portion 73 are integrated and the pin 72 is inserted into the hole 71b, as in the third modified embodiment. Moreover, the connection terminal 70c described in the fourth modified embodiment may be fixed to the through hole 63 which does not have the conductor layer 65 on the inner wall using the bonding layer 90 or fitted into the through hole 63 without using the bonding layer 90, as in the fifth modified embodiment.

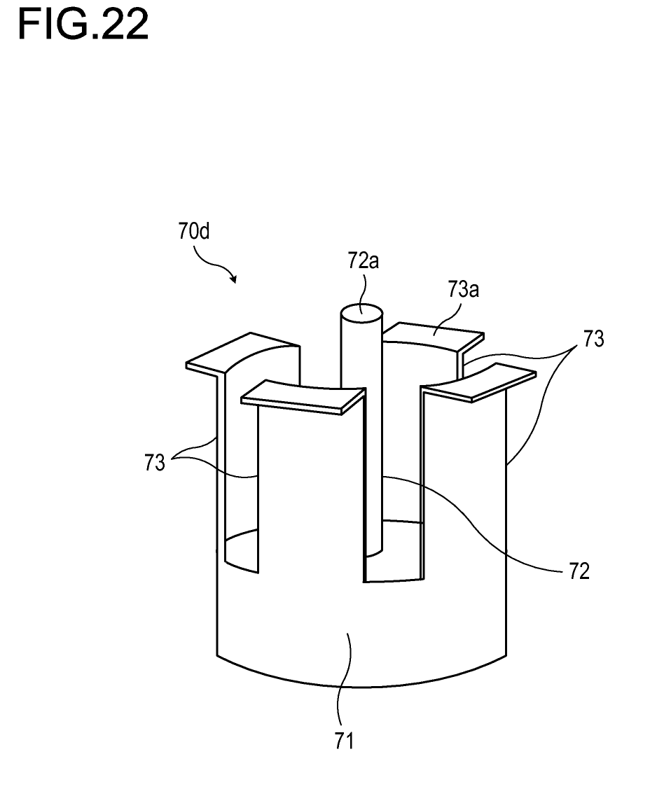

FIG. 22 is an explanatory view of a sixth modified embodiment. FIG. 22 is a schematic perspective view of a main part of a connection terminal according to the sixth modified embodiment.

A connection terminal 70d illustrated in FIG. 22 is different from the above-described connection terminal 70 in that the connection terminal 70d has a structure in which a plurality (for example, four in this modified embodiment) of side wall portions 73 is formed at the periphery of a pedestal portion 71 so as to enclose the pin 72. Flanges 73a are formed at ends of the plurality of side wall portions 73. Flanges 73a at one or more side wall portions 73 may be omitted.

Similarly to the above-described connection terminal 70, even in the connection terminal 70d having the plurality of side wall portions 73, the plurality of side wall portions 73 serves as a guide, so that the connection terminal 70d formed in the through hole 63 of the substrate 60 is suppressed from being significantly oblique. Further, the connection terminal 70d may also be connected to the power supply board 100 while suppressing the stress caused by the misalignment between the pin 72 and the connector 120 from occurring, thereby obtaining the component-mounted circuit board having high connection reliability.

In the meantime, the bending portion 72b as described in the first modified embodiment may be formed in the pin 72 of the connection terminal 70d described in the sixth modified embodiment. Further, the connection terminal 70d described in the sixth modified embodiment may be fitted into the through hole 63 of the substrate 60 as in the second modified embodiment. Further, the connection terminal 70d described in the sixth modified embodiment may have a structure in which the pedestal portion 71 having the hole 71b at the center thereof and the plurality of side wall portions 73 are integrated and the pin 72 is inserted into the hole 71b, as in the third modified embodiment. Further, the connection terminal 70c described in the fourth modified embodiment may have a structure in which a plurality of side wall portions 73 is formed at the periphery of the pedestal portion 71 as in the fifth modified embodiment. Moreover, the connection terminal 70d described in the sixth modified embodiment may be provided in a through hole 63 which has or does not have a conductor layer 65 on an inner wall, using or without using the bonding layer 90.

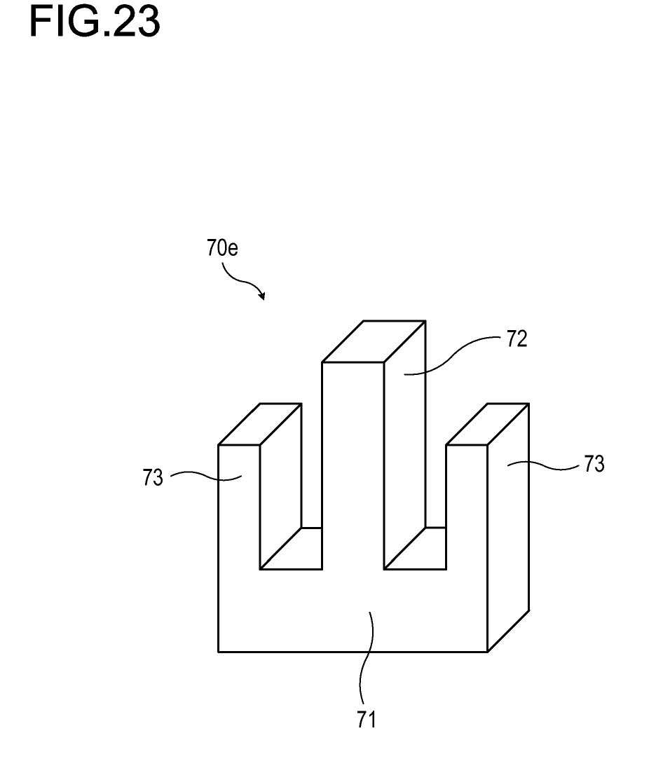

FIG. 23 is an explanatory view of a seventh modified embodiment. FIG. 23 is a schematic perspective view of a main part of a connection terminal according to the seventh modified embodiment.

A connection terminal 70e illustrated in FIG. 23 has a pin 72 provided at a center of a pedestal portion 71 and side wall portions 73 which are provided at both peripheries with the pin 72 of the pedestal portion 71 therebetween. In the connection terminal 70e, widths of the pin 72 and the pair of side wall portions 73 with the pin 72 therebetween in a direction perpendicular to a juxtaposing direction those of are the same as the width of the pedestal portion 71. The connection terminal 70e has the above-described structure, which is different from the above-described connection terminal 70.

The connection terminal 70e may be formed by performing a punching process on a platy member which becomes a material therefor. Further, a chamfering process may be performed on an edge of the connection terminal 70e obtained by performing the punching process.

The through hole 63 of the substrate 60 into which the connection terminal 70e is inserted has a rectangular opening shape or a substantially rectangular opening shape as seen from a plan view and the connection terminal 70e is inserted into the through hole 63 having such an opening shape, to form the system board.

Similarly to the above-described connection terminal 70, even in the connection terminal 70e, the side wall portion 73 serves as a guide, so that the connection terminal 70e inserted into the through hole 63 of the substrate 60 is suppressed from being significantly oblique. Further, the connection terminal 70e may be connected to the power supply board 100 while suppressing the stress caused by the misalignment between the pin 72 and the connector 120 from occurring, thereby obtaining the component-mounted circuit board having high connection reliability.

In the meantime, the bending portion 72b as described in the first modified embodiment may be formed in the pin 72 of the connection terminal 70e described in the seventh modified embodiment. Further, the connection terminal 70e described in the seventh modified embodiment may be fitted into the through hole 63 of the substrate 60 as in the second modified embodiment. Further, the connection terminal 70c described in the fourth modified embodiment may have a structure in which a pair of side wall portions 73 with the pin 72 therebetween is formed at peripheries of the pedestal portion 71 as in the seventh modified embodiment. Moreover, the connection terminal 70e described in the seventh modified embodiment may be provided in a through hole 63 which has or does not have a conductor layer 65 on an inner wall, using or without using the bonding layer 90.

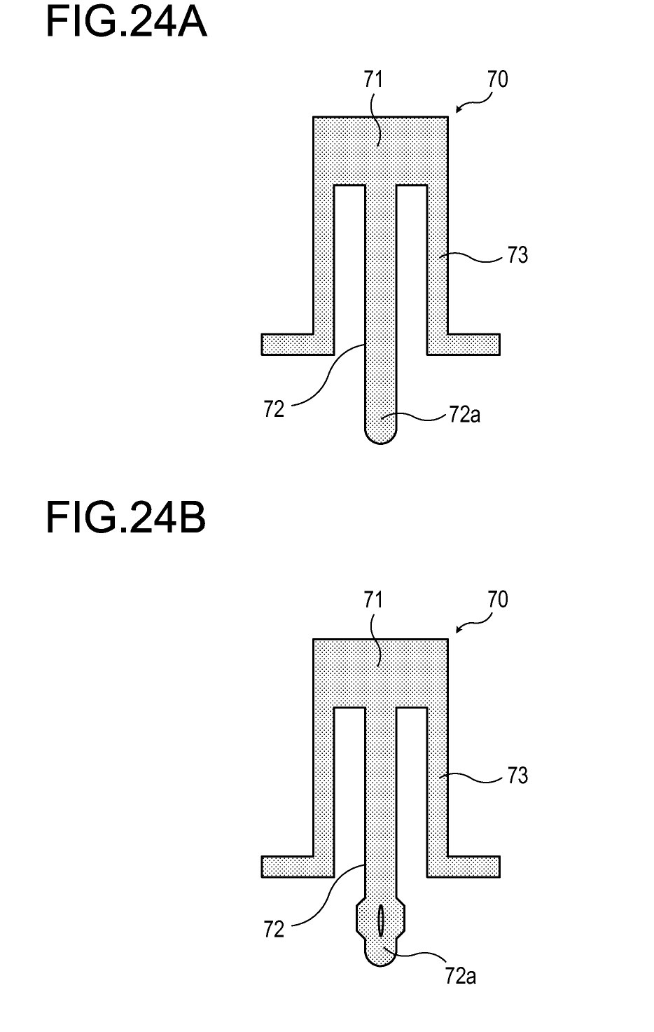

FIGS. 24A and 24B are explanatory views of an eighth modified embodiment. FIG. 24A schematically illustrates a cross-section of a main part of a first example of a connection terminal according to the eighth modified embodiment and FIG. 24B schematically illustrates a cross-section of a main part of a second example of a connection terminal according to the eighth modified embodiment.

A distal end of a pin 72 of a connection terminal 70 may be formed not only to have a flat surface but also to have a rounded shape such as a hemispherical shape, as illustrated in FIG. 24A. When the distal end is formed to have the rounded shape, the distal end of the pin 72 may be more smoothly inserted into an insertion port 120a of a connector 120 which is misaligned from the pin 72. Similarly, distal ends of pins 72 of the connection terminals 70a, 70b, 70c, 70d, and 70e may have a rounded shape.

Further, a distal portion 72a of the pin 72 of the connection terminal 70 which is inserted into the insertion port 120a of the connector 120 may have a press-fit shape as illustrated in FIG. 24B. When the distal portion 72a of the pin 72 is formed to have a press-fit shape, the pin 72 may be more solidly connected to the insertion port 120a of the connector 120. Similarly, the distal portions 72a of the pins 72 of the connection terminals 70a, 70b, 70c, 70d, and 70e may have a press-fit shape.

In the meantime, the methods described in the first to eight modified embodiments may also be applied to the connection terminal 20 and the circuit board 1 according to the first embodiment.

Next, a third embodiment will be described.

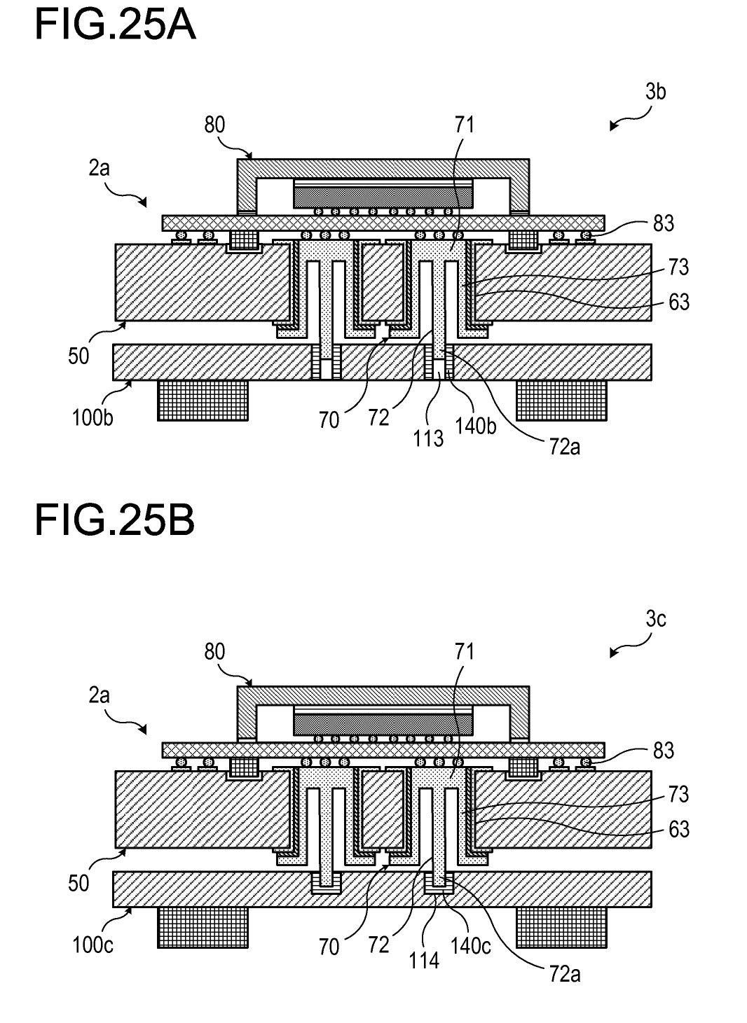

FIGS. 25A and 25B are views illustrating an example of a component-mounted circuit board according to the third embodiment. FIG. 25A schematically illustrates a cross-section of a main part of a first example of a component-mounted circuit board according to the third embodiment and FIG. 25B schematically illustrates a cross-section of a main part of a second example of a component-mounted circuit board according to the third embodiment.

A component-mounted circuit board 3b illustrated in FIG. 25A includes a component-mounted circuit board 2a in which a semiconductor package 80 is mounted on a system board 50, and a power supply board 100b having a terminal 140b into which a pin 72 of a connection terminal 70 of the system board 50 is inserted. The terminal 140b is formed in a through hole 113 which penetrates a substrate 110 of the power supply board 100b, as illustrated in FIG. 25A. A distal portion 72a of the pin 72 is inserted in the concave terminal 140b, so that the power supply board 100b and the system board 50 are electrically connected to each other.

Further, a component-mounted circuit board 3c illustrated in FIG. 25B includes a component-mounted circuit board 2a in which a semiconductor package 80 is mounted on a system board 50, and a power supply board 100c having a terminal 140c into which a pin 72 of a connection terminal 70 of the system board 50 is inserted. The terminal 140c is formed in a concave portion 114 having a bottom which is formed on a substrate 110 of the power supply board 100b, as illustrated in FIG. 25B. A distal portion 72a of the pin 72 is inserted in the concave terminal 140c, so that the power supply board 100c and the system board 50 are electrically connected to each other.

Even when the pin 72 and the terminal 140b or 140c are misaligned while the component-mounted circuit board 3b or 3c is assembled, the distortion caused by the misalignment is absorbed, thereby suppressing the stress from occurring. In the component-mounted circuit board 3b or 3c, a connection distance between the system board 50 and the power supply board 100b or 100c is further shortened, thereby efficiently suppressing the power drop.

The pin 72 of the connection terminal 70 may be connected not only to the power supply board 100 having the connector 120 described in the second embodiment, but also to the power supply board 100b or 100c having the concave terminal 140b or 140c as an insertion port, as in the third embodiment.

In the meantime, also in the component-mounted circuit board 3b or 3c according to the third embodiment, the system board 50 and the connection terminal 70 may be modified in various ways as described in the second embodiment.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A circuit board, comprising:
a substrate;
a through hole formed in the substrate; and
a connection terminal provided in the through hole;
wherein the connection terminal includes a pedestal portion provided within the through hole and a pin which is provided at a center of the pedestal portion and extends from the pedestal portion toward a first surface of the substrate, so that a first end portion protrudes from the first surface.

2. The circuit board according to claim 1, wherein the connection terminal further includes a side wall portion which extends to the first surface from a periphery of the pedestal portion and is spaced apart from the pin.

3. The circuit board according to claim 2, further comprising:
a conductor layer formed on an inner wall of the through hole; and
a bonding layer which is formed between the conductor layer and the side wall portion to bond the conductor layer to the side wall portion.

4. The circuit board according to claim 2, further comprising:
a conductor layer which is formed on an inner wall of the through hole to be in contact with the side wall portion.

5. The circuit board according to claim 1, wherein the pin has a bending portion.

6. The circuit board according to claim 1, wherein the pedestal portion has a hole and the pin is inserted into the hole.

7. The circuit board according to claim 1, further comprising:
a first electronic component which is provided at the first surface side and has a first concave terminal into which the first end portion is inserted.

8. The circuit board according to claim 1, further comprising:
a second electronic component which is provided at a second surface side which is opposite to the first surface and has a second terminal which is bonded to the pedestal portion.

9. The circuit board according to claim 1, wherein the pin extends from the pedestal portion toward a second surface of the substrate which is opposite to the first surface so that a second end portion which is opposite to the first end portion protrudes from the second surface.

10. The circuit board according to claim 9, further comprising:
a third electronic component which is provided at the second surface side and has a third concave terminal into which the second end portion is inserted.

11. A method of manufacturing a circuit board, the method comprising:
preparing a substrate having a through hole; and
providing a connection terminal in the through hole,
wherein the connection terminal includes a pedestal portion provided within the through hole and a pin which is provided at a center of the pedestal portion and extends from the pedestal portion toward a first surface of the substrate, so that a first end portion protrudes from the first surface.

12. The method according to claim 11, further comprising:
preparing a first electronic component having a first concave terminal;
after the providing of the connection terminal, disposing the first electronic component at the first surface side so that the first concave terminal faces the first surface; and
inserting the first end portion into the first concave terminal.

13. The method according to claim 11, further comprising:
preparing a second electronic component having a second terminal; and
after the preparing of the substrate, disposing the second electronic component at a second surface side which is opposite to the first surface so that the second terminal faces the second surface,
wherein the providing of the connection terminal includes inserting the connection terminal including the pedestal portion and the pin into the through hole from the pedestal portion, toward the second surface from the first surface, and bonding the inserted pedestal portion to the second terminal.

14. The method according to claim 13, wherein the substrate includes a conductor layer formed on an inner wall of the through hole,
the connection terminal includes a side wall portion which extends from a periphery of the pedestal portion to the first surface and is spaced apart from the pin, and
the providing of the connection terminal further includes bonding the conductor layer to the side wall portion using a bonding layer.
